(19) United States
(12) Patent Application Publication
(10) Pub. No.: US 2007/0133277 A1
(43) Pub. Date: Jun. 14, 2007

(54) Non-volatile semiconductor memory device

(76) Inventors: Ken Kawai, Osaka (JP); Ryotaro Azuma, Osaka (JP); Akifumi Kawahara, Kyoto (JP); Hitoshi Suwa, Osaka (JP); Hoshihide Haruyama, Kyoto (JP)

Correspondence Address: MCDERMOTT WILL & EMERY LLP, 600 13TH STREET, N.W., WASHINGTON, DC, 20005-3096, US

(21) Appl. No.: 11/602,272

(22) Filed: Nov. 21, 2006

(30) Foreign Application Priority Data
Nov. 29, 2005 (JP) 2005-343479

(51) Int. Cl. G11C 16/04

(52) U.S. Cl. 365/185.03; 365/185.18

(57) ABSTRACT

A memory cell transistor array is composed of a plurality of memory cells having three or more threshold voltage distribution states in a single electric charge accumulation portion. A program sequence control circuit associates each piece of data included in a data set composed of a plurality of data values with any threshold voltage distribution of the three or more threshold voltage distributions, to store the data in the memory cell, and when rewriting the data stored in the memory cell, shifting threshold voltage distributions used for data storage in one direction to perform the data rewrite operation.

### CROSS REFERENCE TO RELATED APPLICATIONS

This Non-provisional application claims priority under 35 U.S.C. §119(a) on Patent Application No. 2005-343479 filed in Japan on Nov. 29, 2005, the entire contents of which are hereby incorporated by reference.

### BACKGROUND OF THE INVENTION

1. Field of the Invention

The present invention relates to a non-volatile semiconductor memory device having a memory cell which stores data using a plurality of threshold voltage distribution states.

2. Description of the Related Art

There is a non-volatile semiconductor memory device which stores data by changing threshold voltage distributions of a memory cell. Conventionally, in such a non-volatile semiconductor memory device, data is rewritten by a three-step rewrite sequence including “preprogram”, “erase”, and “write” (see, for example, JP No. 2001-250388 A).

Specifically, all pieces of data which are randomly written are once programmed into a state ‘0’ (preprogram). Thereafter, the threshold voltage distributions are shifted so that all the pieces of data are changed to a state ‘1’ (erase). Thereafter, the threshold voltage distributions are shifted in accordance with data given by the user so that a random data write operation is performed.

However, in the above-described conventional rewrite sequence, two operation steps (preprogram and erase) are required before writing of random data from the user, so that it is difficult to achieve a high-speed rewrite operation. For example, when preprogram, erase, and random data write operations require the same time, the rewrite sequence requires about three times the time which is required by the random data write operation.

### SUMMARY OF THE INVENTION

In view of the above-described problems, the present invention has been achieved. An object of the present invention is to provide a non-volatile semiconductor memory device capable of reducing a time required for a rewrite sequence.

To achieve the object, an embodiment of the present invention is directed to a non-volatile semiconductor memory device for performing data write and read operations in accordance with an input command, comprising a memory cell array including a plurality of memory cells having three or more threshold voltage distributions in a single electric charge accumulation portion, and a program sequence control circuit for causing the memory cell to store each piece of data included in a data set composed of a plurality of data values, in association with any of the three or more threshold voltage distributions, and shifting a threshold voltage distribution used for data storage in one direction when a rewrite operation is performed with respect to the data stored in the memory cell, thereby performing a data rewrite operation.

Thereby, the threshold voltage distribution of the memory cell is shifted in one direction, so that data is rewritten. Therefore, an erase operation is no longer required, thereby making it possible to significantly reduce a rewrite time.

### BRIEF DESCRIPTION OF THE DRAWINGS

FIG. 1 is a block diagram illustrating a configuration of a non-volatile semiconductor memory device according to Embodiment 1 of the present invention.

FIG. 2 is a diagram illustrating transition states of Vt level distributions when data is rewritten in Embodiment 1 of the present invention.

FIG. 3 is a flowchart indicating a write sequence of Embodiment 1 of the present invention.

FIG. 4 is a flowchart indicating a write sequence of Embodiment 2 of the present invention.

FIG. 5 is a diagram illustrating transition states of Vt level distributions when data is rewritten in Embodiment 2 of the present invention.

FIG. 6 is a flowchart indicating a write sequence of Embodiment 3 of the present invention.

FIG. 7 is a diagram illustrating transition states of Vt level distributions when data is rewritten in Embodiment 3 of the present invention.

FIG. 8 is a block diagram illustrating a configuration of a non-volatile semiconductor memory device according to Embodiment 4 of the present invention.

FIG. 9 is a flowchart indicating setting of a read determination level in Embodiment 4 of the present invention.

FIG. 10 is a block diagram illustrating a configuration of a non-volatile semiconductor memory device according to Embodiment 5 of the present invention.

FIG. 11 is a diagram illustrating a relationship between positions of threshold voltage distributions used for storage of binary data, and a write position of a monitor bit.

FIG. 12 is a flowchart indicating setting of a read determination level in Embodiment 5 of the present invention.

FIG. 13 is a block diagram illustrating a configuration of a non-volatile semiconductor memory device according to Embodiment 6 of the present invention.

FIG. 14 is a diagram illustrating transition states of Vt level distributions when data is rewritten in Embodiment 6 of the present invention.

FIG. 15 is a flowchart indicating a write sequence of Embodiment 6 of the present invention.

FIG. 16 is a block diagram illustrating a configuration of a non-volatile semiconductor memory device according to Embodiment 7 of the present invention.

FIG. 17 is a flowchart indicating setting of a read determination level in Embodiment 7 of the present invention.

FIG. 18 is a block diagram illustrating a configuration of a non-volatile semiconductor memory device according to Embodiment 8 of the present invention.

FIG. 19 is a diagram illustrating transition states of Vt level distributions when data is rewritten in Embodiment 8 of the present invention.

FIG. 20 is a flowchart indicating a write sequence of Embodiment 8 of the present invention.

FIG. 21 is a block diagram illustrating a configuration of a non-volatile semiconductor memory device according to Embodiment 9 of the present invention.

FIG. 22 is a diagram illustrating transition states of Vt level distributions when data is rewritten in Embodiment 9 of the present invention.

FIG. 23 is a flowchart indicating a compression operation of Embodiment 8.

FIG. 24 is a block diagram illustrating a configuration of a non-volatile semiconductor memory device according to Embodiment 10 of the present invention.

FIG. 25 is a flowchart indicating setting of a read determination level in Embodiment 10 of the present invention.

FIG. 26 is a block diagram illustrating a configuration of a non-volatile semiconductor memory device according to Embodiment 11 of the present invention.

FIG. 27 is a flowchart indicating a compression operation of Embodiment 11.

FIG. 28 is a flowchart of setting of a read mode in Embodiment 11 of the present invention.

FIG. 29 is a block diagram illustrating a configuration of a non-volatile semiconductor memory device according to Embodiment 12 of the present invention.

FIG. 30 is a diagram illustrating transition states of Vt level distributions when data is rewritten in Embodiment 12 of the present invention.

FIG. 31 is a flowchart indicating an initialization sequence of Embodiment 12.

FIG. 32 is a block diagram illustrating a configuration of a non-volatile semiconductor memory device according to Embodiment 13 of the present invention.

FIG. 33 is a flowchart indicating an initialization sequence of Embodiment 13.

FIG. 34 is a block diagram illustrating a configuration of a non-volatile semiconductor memory device according to Embodiment 14 of the present invention.

FIG. 35 is a diagram illustrating transitions of Vt distribution states when a write operation is performed in the normal write (long-term guarantee) mode and transitions of Vt distribution states when a write operation is performed in the high-rate write (short-term guarantee) mode.

FIG. 36 is a diagram illustrating total write time dependency of a memory cell threshold voltage.

FIG. 37 is a diagram illustrating transition states of Vt level distributions in a normal write mode and in a high-rate write mode.

FIG. 38 is a flowchart indicating a long-term guaranteeing write operation sequence of Embodiment 14.

FIG. 39 is a block diagram illustrating a configuration of a non-volatile semiconductor memory device according to Embodiment 15 of the present invention.

FIG. 40 is a flowchart indicating a long-term guaranteeing write operation sequence of Embodiment 15.

FIG. 41 is a block diagram illustrating a configuration of a non-volatile semiconductor memory device according to Embodiment 16 of the present invention.

FIG. 42 is a flowchart indicating an erase sequence of Embodiment 16.

FIG. 43 is a block diagram illustrating a configuration of a non-volatile semiconductor memory device according to Embodiment 17 of the present invention.

FIG. 44 is a flowchart indicating an initialization sequence of Embodiment 17.

FIG. 45 is a flowchart indicating an initialization sequence of Embodiment 18.

FIG. 46 is a flowchart indicating an initialization sequence of Embodiment 19.

FIG. 47 is a flowchart indicating an initialization sequence of Embodiment 20.

FIG. 48 is a block diagram illustrating a configuration of a non-volatile semiconductor memory device according to Embodiment 21 of the present invention.

FIG. 49 is a flowchart indicating a write sequence of Embodiment 21.

### DETAILED DESCRIPTION OF THE PREFERRED EMBODIMENTS

Hereinafter, embodiments of the present invention will be described with reference to the accompanying drawings. Note that like parts are designated by like reference numerals and will not be described again.

### Embodiment 1 of the Invention

(Configuration of Non-volatile Semiconductor Memory Device 100)

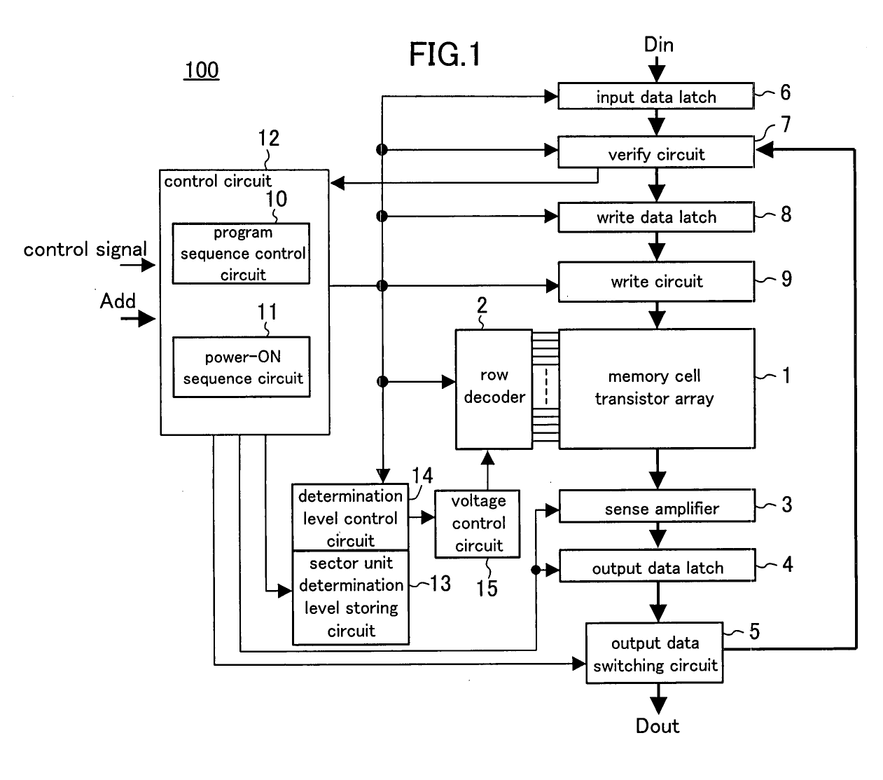

FIG. 1 is a block diagram illustrating a configuration of a non-volatile semiconductor memory device 100 according to Embodiment 1 of the present invention. As illustrated in FIG. 1, the non-volatile semiconductor memory device 100 comprises a memory cell transistor array 1, a row decoder 2, a sense amplifier 3, an output data latch 4, an output data switching circuit 5, an input data latch 6, a verify circuit 7, a write data latch 8, a write circuit 9, a control circuit 12, a sector unit determination level storing circuit 13, a determination level control circuit 14, and a voltage control circuit 15. The non-volatile semiconductor memory device 100 performs data write and read operations, depending on an externally input command (control signal).

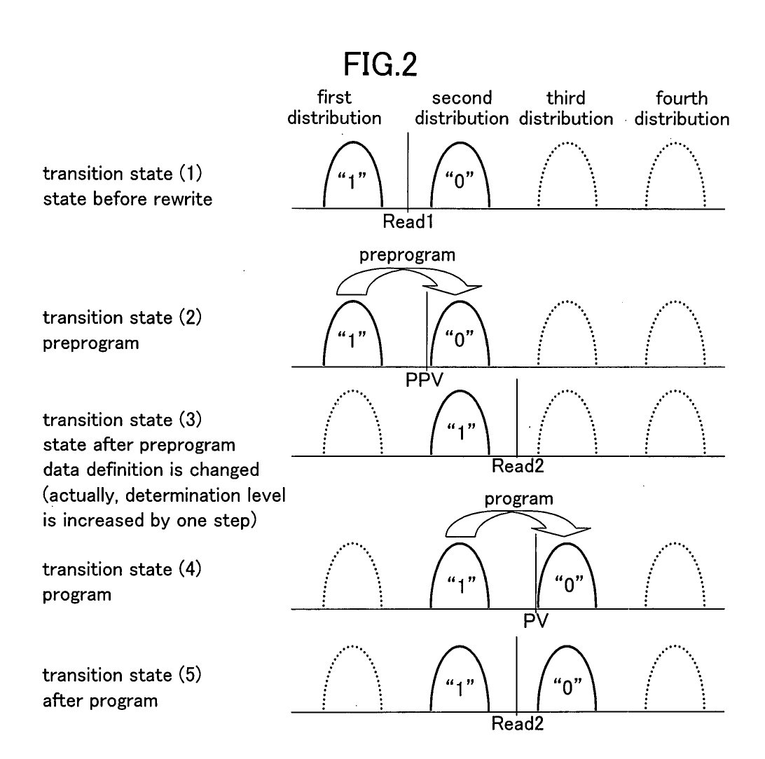

In the memory cell transistor array 1, a plurality of memory cells are arranged in an array. Each memory cell is composed of a transistor whose threshold voltage level (Vt level) changes, depending on an amount of electric charges accumulated in a single electric charge accumulation portion. The memory cell stores data in association with the threshold voltage. The memory cell (transistor) has three or more distributions of the Vt level in the single electric charge accumulation portion. FIG. 2 illustrates transition states of the Vt level distributions when data is stored. In FIG. 2, the horizontal axis represents the Vt level. In this embodiment, two consecutive distributions of a first Vt level distribution to a third Vt level distribution are used to store data. Specifically, data ‘0’ is invariably assigned to the upper one of two consecutive Vt distributions, while data ‘1’ is assigned to the lower distribution. In other words, each memory cell functions as a binary memory. For example, in a transition state (1) of FIG. 2, the first distribution and the second distribution are used to store data, and the third distribution and a fourth distribution are not used to store data. When the first distribution and the second distribution are used to store data, an output potential of a memory cell from which data is to be read out is compared with a determination level Read1 (see FIG. 2) to detect whether the data is ‘0’ or ‘1’.

The row decoder 2 selects an arbitrary memory cell row.

The sense amplifier 3 compares the output potential of a selected memory cell with a potential which is a reference for determining data (read determination level), to detect whether the data is ‘0’ or ‘1’.

The output data latch 4 latches output data of the sense amplifier 3.

The output data switching circuit 5 selectively switches between outputting an output of the output data latch 4 to an output Dout (to the outside), and feeding the output of the output data latch 4 back to the verify circuit 7.

The input data latch 6 latches externally input data Din.

The verify circuit 7 compares data output by the input data latch 6 with data output by the output data switching circuit 5, and outputs a comparison result signal indicating the presence or absence of the difference. The verify circuit 7 also compares any one of data ‘1’ and data ‘0’ with the data output by the output data switching circuit 5, and outputs a comparison result signal indicating the presence or absence of the difference. Here, comparison using data ‘1’ is referred to as All-‘1’ determination, and comparison using data ‘0’ is referred to as All-‘0’ determination.

The write data latch 8 latches input write data.

The write circuit 9 performs a write operation with respect to an arbitrary bit of the memory cell transistor array 1 in accordance with a value of output data of the write data latch 8.

The control circuit 12 comprises a program sequence control circuit 10 and a power-ON sequence control circuit 11, and controls the write and read operations of the non-volatile semiconductor memory device 100, such as, for example, specifying read determination level information (described below) of each sector unit during a read operation.

The program sequence control circuit 10 controls the write operation of the non-volatile semiconductor memory device 100.

The power-ON sequence control circuit 11 specifies a read determination level when power is turned ON.

The sector unit determination level storing circuit 13 stores the read determination level information specified by the power-ON sequence control circuit 11.

The determination level control circuit 14 receives information output by the sector unit determination level storing circuit 13 and sets the read determination level into the voltage control circuit 15.

The voltage control circuit 15 controls a voltage of a memory cell row of an arbitrary sector in the memory cell transistor array 1 in accordance with an output of the determination level control circuit 14.

(Operation of Non-volatile Semiconductor Memory Device 100)

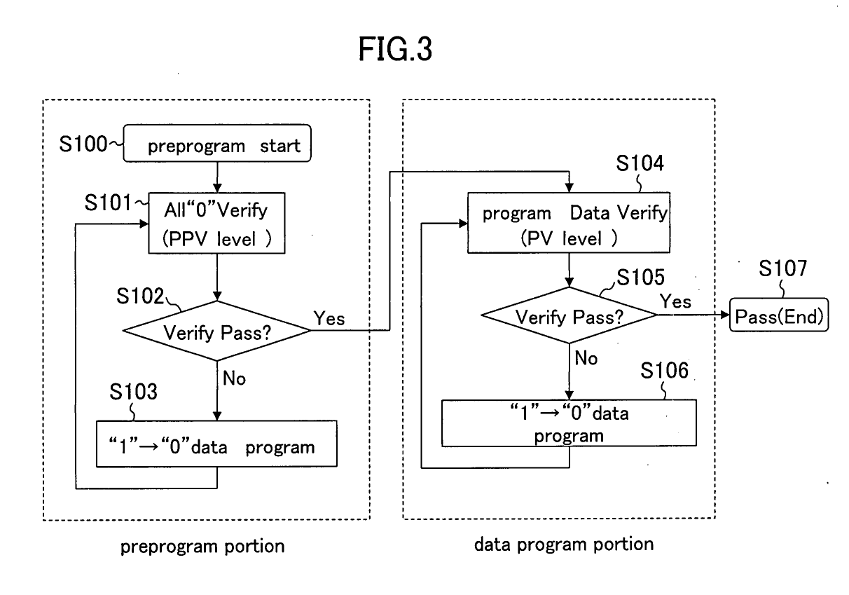

The non-volatile semiconductor memory device 100 performs a process indicated by a flowchart of FIG. 3 to rewrite data stored in a memory cell in a sector to be rewritten. Note that steps S100 to S103 of FIG. 3 are referred to as a preprogram portion, and steps S104 to S107 are referred to as a data program portion.

Firstly, a circuit operation of the preprogram portion (steps S100 to S103) will be described.

(Step S100)

In a state before the start of a rewrite operation, as illustrated in the transition state (1) of FIG. 2, the first distribution means data ‘1’ and the second distribution means data ‘0’ in the memory cell transistor array 1. In this state, the sector unit determination level storing circuit 13 stores information indicating the determination level Read 1.

(Step S101)

Initially, all memory cells to be rewritten are temporarily set to be in the second distribution state.

In this case, in order to set a write determination level for determining a written state to be a level PPV (described below), a signal indicating “program verify” (output information) is sent from the program sequence control circuit 10 to the determination level control circuit 14. The determination level control circuit 14 controls an output voltage of the voltage control circuit 15 to be at the level PPV which is slightly higher than a read determination level (the determination level Read1) stored by the sector unit determination level storing circuit 13. Thereby, the output voltage of the voltage control circuit 15 is increased from the determination level Read1 to the level PPV. The output voltage of the voltage control circuit 15 is applied via the row decoder 2 to a word line connected to the memory cell to be rewritten of the memory cell transistor array 1.

Next, an activation signal is sent from the control circuit 12 to the sense amplifier 3 and the output data latch 4. Thereby, the sense amplifier 3 is activated, so that data of the memory cell on the activated word line is read out. With timing when the output data of the sense amplifier 3 is settled, the output data latch 4 latches the data. The output data latched by the output data latch 4 is sent via the output data switching circuit 5 to the verify circuit 7.

Next, data to be compared in the verify circuit 7 is set to be data for All-‘0’ determination in accordance with a command from the control circuit 12. Thereby, in the verify circuit 7, data ‘0’ is compared with the output data of the output data latch 4 fed back from the output data switching circuit 5, so that a comparison result signal is output. When the comparison result indicates that the two pieces of data match each other, a TRUE signal is sent from the verify circuit 7 to the program sequence control circuit 10.

(Step S102)

In this step, the program sequence control circuit 10 receives the comparison result signal from the verify circuit 7 and determines the next operation. Specifically, when the comparison result signal from the verify circuit 7 is a TRUE signal, the circuit operation goes to the data program portion (steps S104 to S107), and when the comparison result signal is a FALSE signal indicating mismatch, the circuit operation goes to a process of step S103.

(Step S103)

In this step, data ‘0’ is written into a memory cell which stores data ‘1’ (see a transition state (2) of FIG. 2). Specifically, data ‘0’ is sent to and latched by the write data latch 8, and the latched data is set into the write circuit 9. Thereby, the write circuit 9 performs a write operation with respect to the selected memory cell for a predetermined period of time. When the data write operation is finished, the circuit operation goes to the process of step S101. The processes of steps S101 to S103 are performed in this manner with respect to all pieces of data in a sector, so that all memory cells in the sector are temporarily shifted from the lower threshold voltage distribution state to the upper threshold voltage distribution state (see a transition state (3) of FIG. 2). As described above, the write operation for shifting a threshold level is hereinafter referred to as “preprogram”.

Next, a circuit operation in the data program portion (steps S104 to S107) will be described.

(Step S1104)

When the circuit operation goes to the data program portion after the preprogram portion is finished, the memory cell to be rewritten in the sector is in the second distribution state.

At this time, since the read determination level is the determination level Read1, the second distribution state means data ‘0’. In this step, initially, the meaning of the second distribution state is changed into data ‘1’. Specifically, in accordance with a signal from the control circuit 12, the read determination level information stored in the sector unit determination level storing circuit 13 is changed into information indicating a determination level Read2.

Next, a signal indicating “program verify” is sent from the program sequence control circuit 10 to the determination level control circuit 14. The determination level control circuit 14 sets the output voltage of the voltage control circuit 15 to be at a determination level PV which is slightly higher than a determination level used during a data read operation (the determination level Read2) so as to provide a margin with respect to the second distribution level. Thereby, the output voltage of the voltage control circuit 15 is increased from the determination level Read2 to the determination level PV. The determination level PV is a voltage level for determining a written state during a program verify operation. The output voltage of the voltage control circuit 15 is applied via the row decoder 2 to the word line connected to the memory cell to be rewritten of the memory cell transistor array 1.

Next, an activation signal is sent from the control circuit 12 to the sense amplifier 3 and the output data latch 4. Thereby, the sense amplifier 3 is activated, so that data is read from the memory cell on the activated word line. With timing when the output data of the sense amplifier 3 is settled, the output data latch 4 latches the data. The output data latched by the output data latch 4 is sent via the output data switching circuit 5 to the verify circuit 7.

The verify circuit 7 compares the input data Din latched in the input data latch 6 with the output data of the output data latch 4 fed back from the output data switching circuit 5 in accordance with a command from the control circuit 12. When the comparison result indicates that the two pieces of data match each other, a TRUE signal is sent from the verify circuit 7 to the program sequence control circuit 10.

(Step S105)

In this step, the program sequence control circuit 10 receives the comparison result signal from the verify circuit 7 and determines to the next operation. Specifically, when the comparison result signal from the verify circuit 7 is a TRUE signal, the circuit operation goes to a process of step S107 and is ended. When the comparison result signal is a FALSE signal indicating mismatch, the circuit operation goes to a process of step S1106.

(Step S106)

In this step, data ‘0’ is written into a memory cell for which the comparison result in the verify circuit 7 indicates mismatch. Specifically, data ‘0’ is sent to and latched by the write data latch 8, and the latch data is set into the write circuit 9. Thereby, the write circuit 9 performs a write operation with respect to the selected memory cell for a predetermined period of time (see a transition state (4) of FIG. 2).

When a write operation of a piece of data is finished, the circuit operation goes to the process of step S104. The above-described series of processes (steps S104 to S106) are repeatedly performed until all pieces of input data Din are completely written.

As described above, in this embodiment, the memory cell having three or more Vt level distributions in a single electric charge accumulation portion is used, and data ‘0’ and data ‘1’ are assigned to two consecutive Vt level distributions. When data is rewritten, the first distribution state or the second distribution state is temporarily changed into the second distribution state (i.e., a Vt level distribution used for storage is shifted in one direction) before the data is rewritten (see a transition state (5) of FIG. 2). Therefore, according to this embodiment, when data is rewritten, the data erase operation which is performed in conventional non-volatile semiconductor memory devices is no longer required, thereby significantly reducing a time required for a rewrite operation.

### Embodiment 2 of the Invention

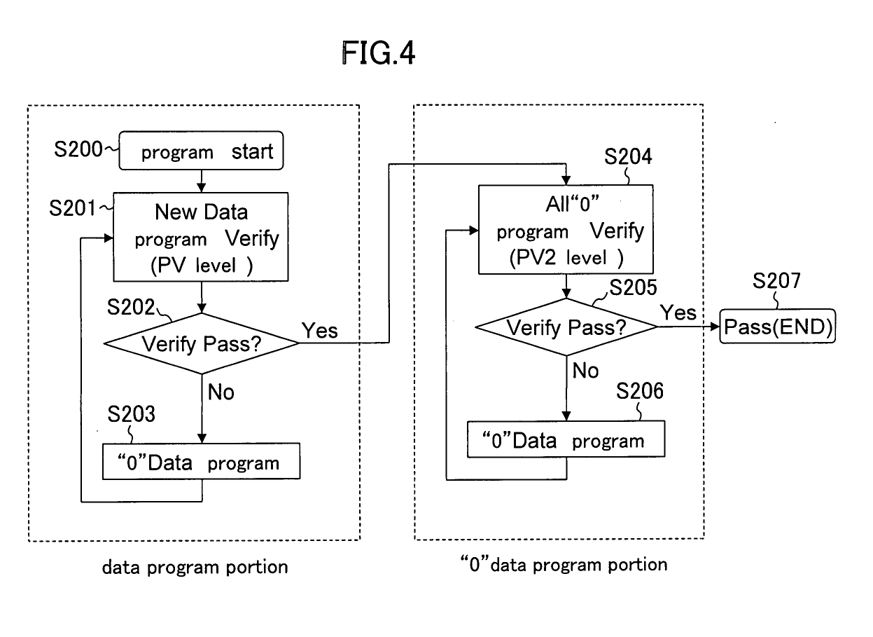

The non-volatile semiconductor memory device 100 of Embodiment 1 may be controlled as indicated in a flowchart of FIG. 4. The write sequence is characterized in that the first distribution state or the second distribution state is directly shifted to the second distribution state or the third distribution (transition between Vt distributions) in accordance with information to be written.

Hereinafter, a process of each step in the flowchart of FIG. 4 will be described. Note that steps S200 to S203 are referred to as a data program portion, and steps S204 to S207 are referred to as a ‘0’ data program portion.

Firstly, an operation of the data program portion (steps S200 to S203) will be described.

(Step S200)

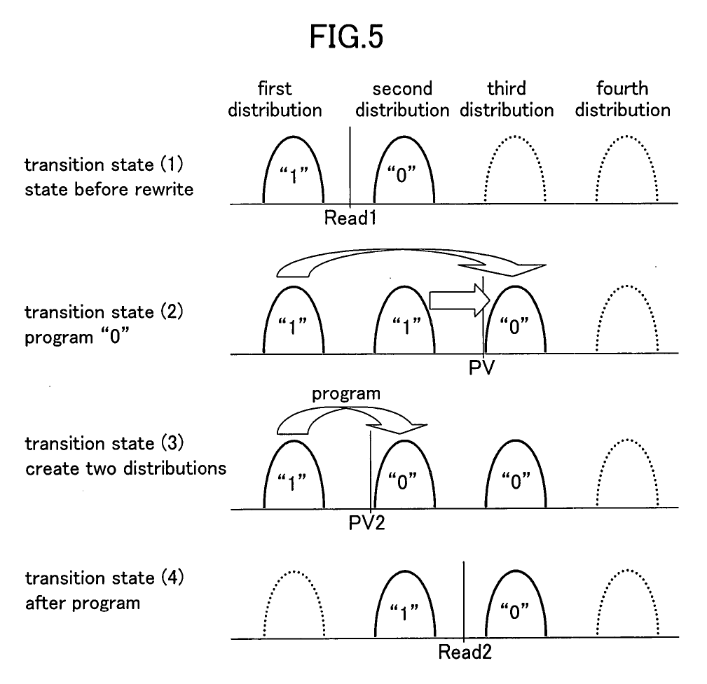

In a state before the start of a rewrite operation, as illustrated in a transition state (1) of FIG. 5, the first distribution means data ‘1’ and the second distribution means data ‘0’ in the memory cell transistor array 1.

(Step S201)

In this step, initially, the meaning of the second distribution state is changed into data ‘1’. Specifically, the read determination level information stored in the sector unit determination level storing circuit 13 is changed into information indicating the determination level Read2 in accordance with a signal from the control circuit 12.

Next, a signal meaning “program verify” is sent from the program sequence control circuit 10 to the determination level control circuit 14. The determination level control circuit 14 sets the output voltage of the voltage control circuit 15 to be the determination level PV which is a level slightly higher than a determination level during a data read operation (the determination level Read2) so as to provide a margin with respect to the second distribution. Thereby, the output voltage of the voltage control circuit 15 is increased from the determination level Read2 to the determination level PV. The determination level PV is a voltage level which is used to determine a distribution state during a program verify operation. The output voltage of the voltage control circuit 15 is applied via the row decoder 2 to the word line connected to the memory cell to be rewritten of the memory cell transistor array 1.

Next, an activation signal is sent from the control circuit 12 to the sense amplifier 3 and the output data latch 4. Thereby, the sense amplifier 3 is activated, so that data is read out from the memory cell on the activated word line. With timing when the output data of the sense amplifier 3 is settled, the output data latch 4 latches the data. The output data latched by the output data latch 4 is sent via the output data switching circuit 5 to the verify circuit 7.

The verify circuit 7 compares the input data Din latched in the input data latch 6 with the output data of the output data latch 4 fed back from the output data switching circuit 5 in accordance with a command from the control circuit 12. When the comparison result indicates that the two pieces of data match each other, a TRUE signal is sent from the verify circuit 7 to the program sequence control circuit 10.

(Step S202)

In this step, the program sequence control circuit 10 receives a comparison result signal from the verify circuit 7, and determines the next operation. Specifically, when the comparison result signal from the verify circuit 7 is a TRUE signal, the circuit operation goes to a process of step S204. When the comparison result signal is a FALSE signal indicating mismatch, the circuit operation goes to a process of step S203.

(Step S203)

In this step, data ‘0’ is written into a memory cell for which the comparison result in the verify circuit 7 indicates mismatch. Specifically, data ‘0’ is sent to and latched by the write data latch 8, and the latch data is set into the write circuit 9. Thereby, the write circuit 9 performs a write operation with respect to the selected memory cell for a predetermined period of time (see a transition state (2) of FIG. 5). Note that the read determination level in this case is the level PV.

After the data write operation is finished, the circuit operation goes to the process of step S201. The processes of steps S201 to S203 are performed in this manner with respect to all pieces of data in a sector.

(Step S204)

In this step, all memory cells in the first distribution state are changed into the second distribution state.

In this case, in order to set the read determination level to be a level PV2, a signal meaning “program verify” (output information) is sent from the program sequence control circuit 10 to the determination level control circuit 14. The determination level control circuit 14 controls the output voltage of the voltage control circuit 15 into the level PV2 which is a level slightly higher than a read determination level (the determination level Read1) stored by the sector unit determination level storing circuit 13. Thereby, the output voltage of the voltage control circuit 15 is increased from the determination level Read1 to the level PV2 (see a transition state (3) of FIG. 5). The output voltage of the voltage control circuit 15 is applied via the row decoder 2 to the word line connected to the memory cell to be rewritten of the memory cell transistor array 1.

Next, an activation signal is sent from the control circuit 12 to the sense amplifier 3 and the output data latch 4. Thereby, the sense amplifier 3 is activated, so that data is read out from the memory cell on the activated word line. With timing when the output data of the sense amplifier 3 is settled, the output data latch 4 latches the data. The output data latched by the output data latch 4 is sent via the output data switching circuit 5 to the verify circuit 7.

Next, data to be compared in the verify circuit 7 is set to be data for All-‘0’ determination in accordance with a command from the control circuit 12. Thereby, in the verify circuit 7, data ‘0’ is compared with the output data of the output data latch 4 fed back from the output data switching circuit 5, so that a comparison result signal is output. When the comparison result indicates that the two pieces of data match each other, a TRUE signal is sent from the verify circuit 7 to the program sequence control circuit 10.

(Step S205)

In this step, the program sequence control circuit 10 receives the comparison result signal from the verify circuit 7 and determines the next operation. Specifically, when the comparison result signal from the verify circuit 7 is a TRUE signal, the circuit operation goes to step S207), and is ended. When the comparison result signal is a FALSE signal indicating mismatch, the circuit operation goes to a process of step S206.

(Step S206)

In this step, data ‘0’ is written into a memory cell for which the comparison result in the verify circuit 7 indicates mismatch. Specifically, data ‘0’ is sent to and latched by the write data latch 8, and the latch data is set into the write circuit 9. Thereby, the write circuit 9 performs a write operation with respect to the selected memory cell for a predetermined period of time.

When a write operation of a piece of data is finished, the circuit operation goes to the process of step S204. The above-described series of processes (steps S204 to S206) are repeatedly performed until all pieces of input data Din are completely written.

As described above, in this embodiment, a state in which the first distribution and the second distribution are used is directly shifted to a state in which the second distribution and the third distribution are used, in accordance with write information, thereby rewriting memory information. Therefore, according to this embodiment, when data is rewritten, the data erase operation which is performed in conventional non-volatile semiconductor memory devices is no longer required, thereby significantly reducing a time required for a rewrite operation.

### Embodiment 3 of the Invention

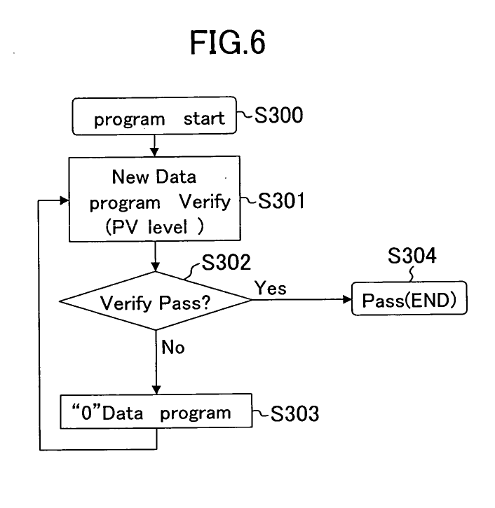

The non-volatile semiconductor memory device 100 of Embodiment 1 may be controlled as indicated in a flowchart of FIG. 6. The write sequence is characterized in that a state in which a first Vt distribution to an n-th Vt distribution are used is changed into a state in which the first Vt dimension to an (n+1)-th Vt dimension are used (Vt dimensions to be used are extended and transitioned) in accordance with write information.

Hereinafter, a process of each step in the flowchart of FIG. 6 will be described.

(Step S300)

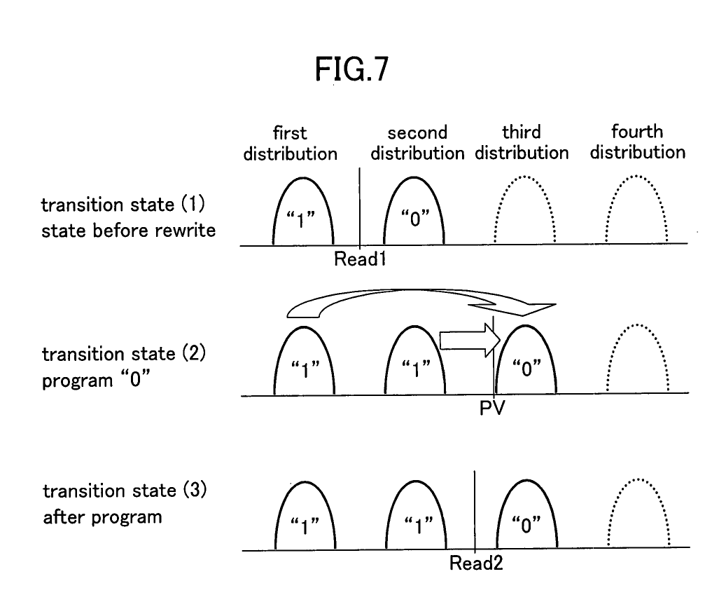

In a state before the start of a rewrite operation, the first and second distributions are assumed to be used for storage of information. As illustrated in a transition state (1) of FIG. 7, the first distribution means data ‘1’ and the second distribution means data ‘0’ in the memory cell transistor array 1.

(Step S301)

In this step, initially, the meaning of the second distribution state is changed into data ‘1’. Specifically, the read determination level information stored in the sector unit determination level storing circuit 13 is changed into information indicating the determination level Read2 in accordance with a signal from the control circuit 12.

Next, a signal meaning “program verify” is sent from the program sequence control circuit 10 to the determination level control circuit 14. The determination level control circuit 14 sets the output voltage of the voltage control circuit 15 to be the determination level PV which is a level slightly higher than a determination level during a data read operation (the determination level Read2) so as to provide a margin with respect to the second distribution. Thereby, the output voltage of the voltage control circuit 15 is increased from the determination level Read2 to the determination level PV. The output voltage of the voltage control circuit 15 is applied via the row decoder 2 to a word line connected to a memory cell to be rewritten of the memory cell transistor array 1.

Next, an activation signal is sent from the control circuit 12 to the sense amplifier 3 and the output data latch 4. Thereby, the sense amplifier 3 is activated, so that data is read out from the memory cell on the activated word line. With timing when the output data of the sense amplifier 3 is settled, the output data latch 4 latches the data. The output data latched by the output data latch 4 is sent via the output data switching circuit 5 to the verify circuit 7.

The verify circuit 7 compares the input data Din latched in the input data latch 6 with the output data of the output data latch 4 fed back from the output data switching circuit 5 in accordance with a command from the control circuit 12. When the comparison result indicates that the two pieces of data match each other, a TRUE signal is sent from the verify circuit 7 to the program sequence control circuit 10.

(Step S302)

In this step, the program sequence control circuit 10 receives a comparison result signal from the verify circuit 7, and determines the next operation. Specifically, when the comparison result signal from the verify circuit 7 is a TRUE signal, the circuit operation goes to a process of step S304. When the comparison result signal is a FALSE signal indicating mismatch, the circuit operation goes to a process of step S303.

(Step S303)

In this step, data ‘0’ is written into a memory cell for which the comparison result in the verify circuit 7 indicates mismatch. Specifically, data ‘0’ is sent to and latched by the write data latch 8, and the latch data is set into the write circuit 9. Thereby, the write circuit 9 performs a write operation with respect to the selected memory cell for a predetermined period of time (see a transition state (2) of FIG. 7). Note that the read determination level in this case is the level PV.

After the data is completely written, the circuit operation goes to the process of step S301. The processes of steps S301 to S303 are performed with respect to all pieces of data in a sector.

As described above, in this embodiment, the state in which the first to n-th Vt distributions are used is extended into the state in which the first to (n+1)-th Vt distributions are used, in accordance with write information. Therefore, also in this embodiment, when data is rewritten, the data erase operation which is performed in conventional non-volatile semiconductor memory devices is no longer required, thereby significantly reducing a time required for a rewrite operation.

### Embodiment 4 of the Invention

In the non-volatile semiconductor memory devices of Embodiments 1 to 3, unless Vt distributions which are used for storage of information are determined, a read determination level is not determined, so that a correct read operation cannot be performed. Therefore, in the non-volatile semiconductor memory device 100, the read determination level needs to be initialized, depending on the Vt distributions used in the memory cell transistor array 1, after power is turned ON.

In a non-volatile semiconductor memory device 400 according to Embodiment 4 of the present invention, a non-volatile memory area is provided separately from the memory cell transistor array 1 used by the user, and information indicating positions of threshold voltage distributions used in the memory cell transistor array 1 (used distribution position information) is previously stored in the non-volatile memory area (hereinafter referred to as a used distribution position storing area). The used distribution position information is read out from the used distribution position storing area immediately after power is turned ON, and a read determination level for a user data storing area is set.

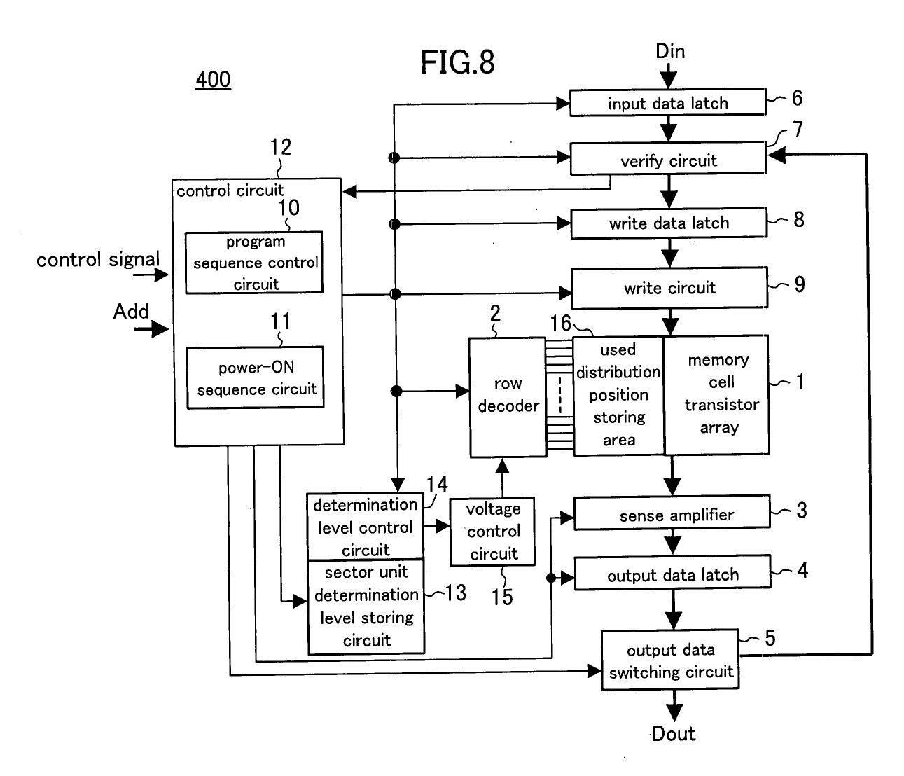

FIG. 8 is a block diagram illustrating a configuration of the non-volatile semiconductor memory device 400. As illustrated in FIG. 8, the non-volatile semiconductor memory device 400 has the same configuration as that of the non-volatile semiconductor memory device 100, except that a used distribution position storing area 16 corresponding to each sector is added.

The used distribution position storing area 16 is composed of memory cells of the same type as that of the memory cells constituting the memory cell transistor array 1. The used distribution position storing area 16 stores the positions of Vt distributions used in memory cells in a corresponding sector. Two fixed Vt distributions are used for the used distribution position storing area 16 to store information.

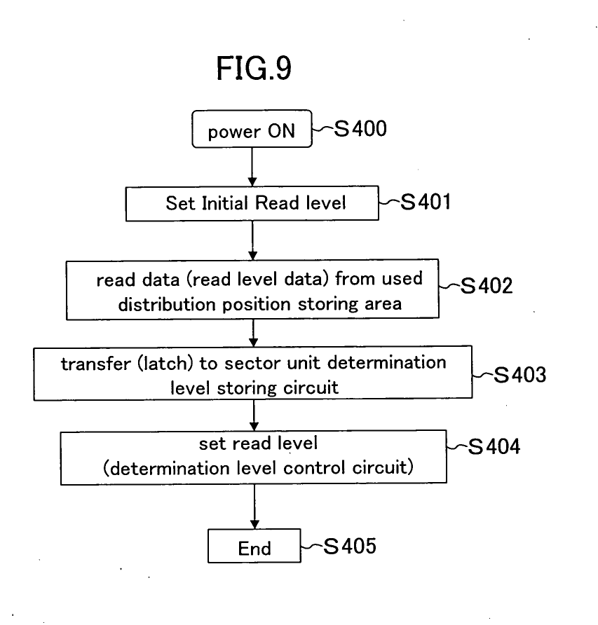

In the non-volatile semiconductor memory device 400, a circuit operation indicated by a flowchart of FIG. 9 is performed to set a read determination level.

(Step S400)

The non-volatile semiconductor memory device 400 is powered ON.

(Step S401)

The power-ON sequence control circuit 11 initializes the read determination level information stored in the sector unit determination level storing circuit 13 so that data stored in the used distribution position storing area 16 can be detected.

(Step S402)

Next, used distribution position information is read out from the used distribution position storing area 16 using the sense amplifier 3. The output data latch 4 latches the used distribution position information output by the sense amplifier 3.

(Step S403)

The power-ON sequence control circuit 11 transfers read determination level information corresponding to the used distribution position information latched by the output data latch 4, via the output data switching circuit 5, to the sector unit determination level storing circuit 13. The sector unit determination level storing circuit 13 stores the transferred read determination level information.

(Step S404)

Thereafter, the determination level control circuit 14 controls the output voltage of the voltage control circuit 15 into the read determination level stored in the sector unit determination level storing circuit 13.

(Step S405)

When the circuit operation finally reaches step S405, the setting of a read determination level is completed.

As described above, according to this embodiment, after power is turned ON, a read determination level with respect to the memory cell transistor array 1 is appropriately set. Therefore, even when Vt distributions for storing information are shifted, a correct read operation can be performed.

### Embodiment 5 of the Invention

Another embodiment of initialization of a read determination level will be described.

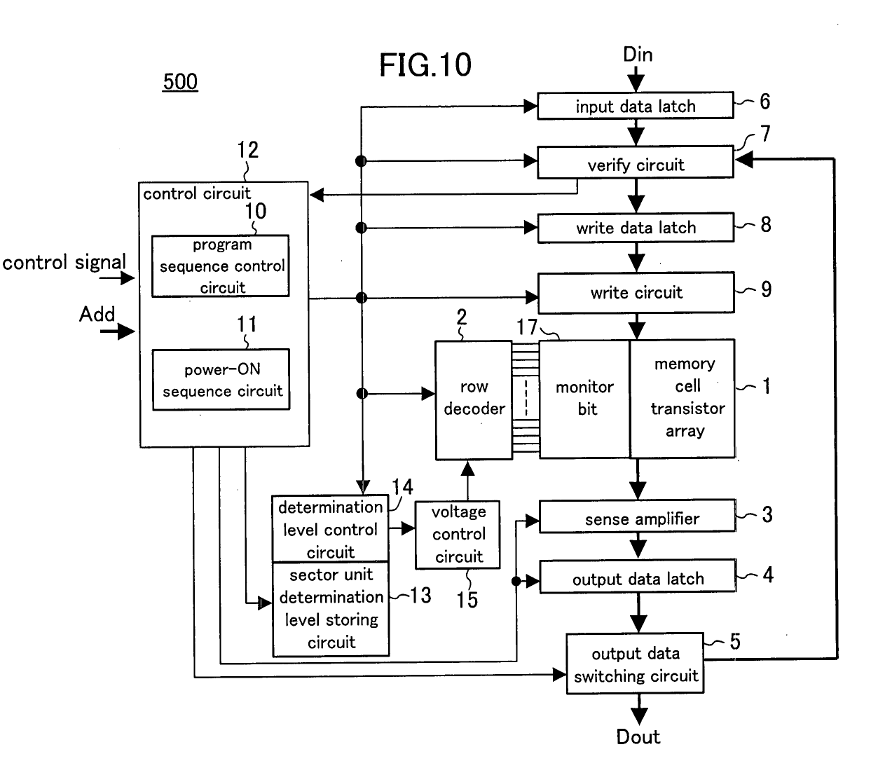

FIG. 10 is a block diagram illustrating a configuration of a non-volatile semiconductor memory device 500. As illustrated in FIG. 10, the non-volatile semiconductor memory device 500 has the same configuration as that of the non-volatile semiconductor memory device 100, except that a monitor bit 17 corresponding to each sector is added.

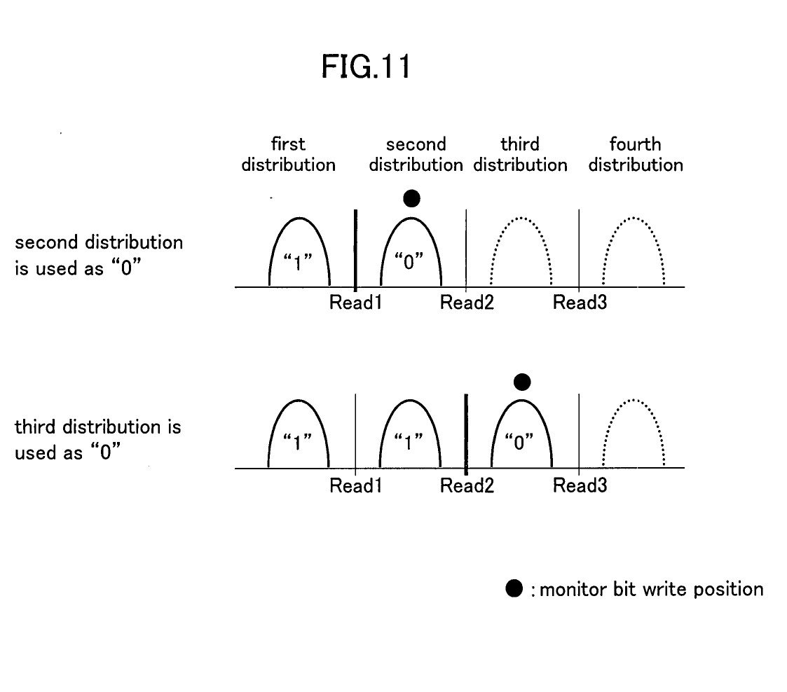

The monitor bit 17 is composed of memory cells of the same type as that of the memory cells constituting the memory cell transistor array 1. The monitor bit 17 uses the same Vt distributions as those of a memory cell of a corresponding sector, and invariably stores data ‘0’. FIG. 11 is a diagram illustrating a relationship between positions of threshold voltage distributions used for storage of binary data in the memory cell transistor array 1, and a write position of the monitor bit. Regarding the case where the second distribution is used as data ‘0’ and the case where the third distribution is used as data ‘0’, the respective write positions of the monitor bit 17 are indicated by closed circles.

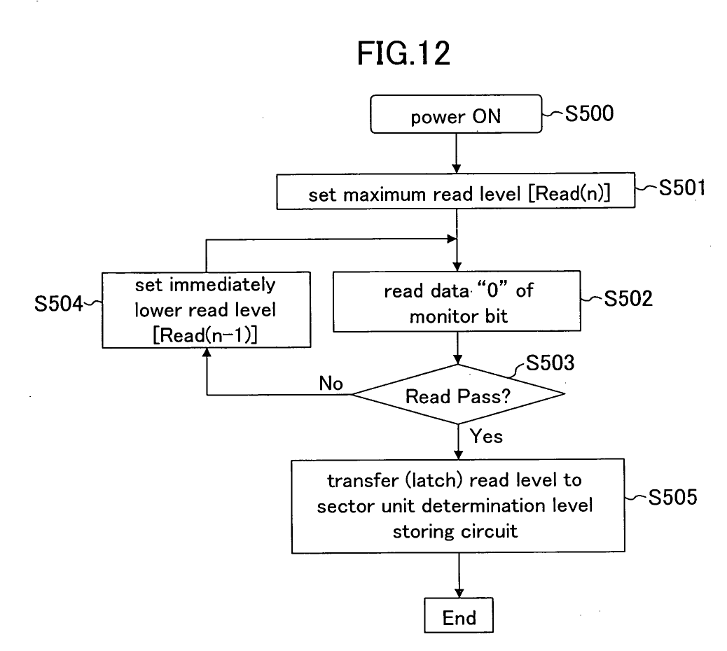

The non-volatile semiconductor memory device 500 is characterized in that, immediately after power is turned ON, the monitor bit 17 is used to specify a threshold voltage distribution position used for storage of data ‘0’, and a read determination level of the user data storing area is set. Specifically, in the non-volatile semiconductor memory device 500, a process indicated by a flowchart of FIG. 12 is performed to set a read determination level.

(Step S500)

The non-volatile semiconductor memory device 500 is powered ON.

(Step S501)

In order to determine a read determination level with respect to the monitor bit 17 by successively changing the read determination level from a maximum level thereof, the power-ON sequence control circuit 11 sends a signal to the determination level control circuit 14 so that the read determination level with respect to the monitor bit 17 becomes the maximum level. The determination level control circuit 14 controls the output voltage of the voltage control circuit 15 into the maximum read determination level (see a determination level Read3 of FIG. 11).

(Step S502)

Next, a read operation with respect to the monitor bit 17 is performed using the sense amplifier 3. The output data latch 4 latches used distribution position information output by the sense amplifier 3. The output data latched by the output data latch 4 is sent via the output data switching circuit 5 to the verify circuit 7.

The power-ON sequence control circuit 11 previously sets data to be compared in the verify circuit 7 to be data ‘0’.

The verify circuit 7 compares data ‘0’ with the output data of the output data latch 4, and outputs the comparison result to the power-ON sequence control circuit 11.

(Step S503)

When the comparison result of the verify circuit 7 indicates that data ‘0’ and the output data of the output data latch 4 match each other, the circuit operation goes to a process of step S505. When the comparison result indicates mismatch, the circuit operation goes to a process of step S504.

(Step S504)

The power-ON sequence control circuit 11 sets the read determination level to be an immediately lower level (e.g., from the determination level Read3 to the determination level Read2 in FIG. 11). Thereafter, the circuit operation goes to the process of step S502.

(Step S505)

In this step, a read determination level is set.

The power-ON sequence control circuit 11 controls the determination level control circuit 14 so that read determination level information corresponding to a current read determination level is stored into the sector unit determination level storing circuit 13. Thereby, the setting of a read determination level is completed.

As described above, also in this embodiment, after power is turned ON, a read determination level with respect to the memory cell transistor array 1 is appropriately set. Thereby, even when Vt distributions for storage of information are shifted, a correct read operation can be performed.

### Embodiment 6 of the Invention

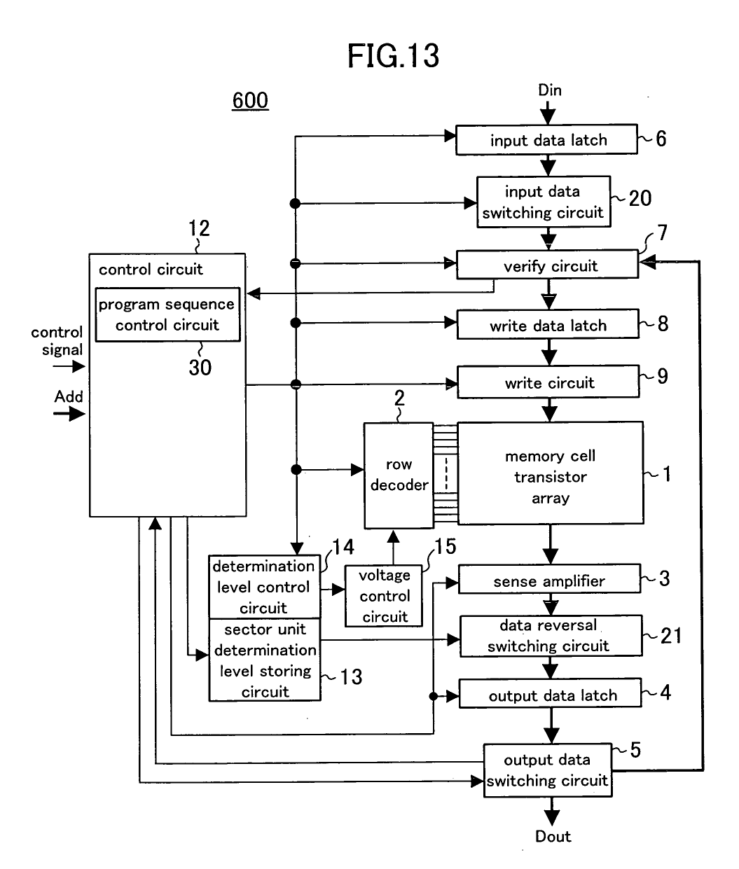

FIG. 13 is a block diagram illustrating a configuration of a non-volatile semiconductor memory device 600 according to Embodiment 6 of the present invention. As illustrated in FIG. 13, the non-volatile semiconductor memory device 600 has the same configuration as that of the non-volatile semiconductor memory device 100, except that a program sequence control circuit 30 is provided instead of the program sequence control circuit 10, and an input data switching circuit 20 and a data reversal switching circuit 21 are added.

The input data switching circuit 20 switches whether the output data of the input data latch 6 or data ‘0’ is output to the verify circuit 7, in accordance with a control of the program sequence control circuit 30.

The data reversal switching circuit 21 outputs the output data of the sense amplifier 3 to the output data latch 4 directly or after reversal thereof, in accordance with a control of the program sequence control circuit 30.

The program sequence control circuit 30 controls a write operation in the non-volatile semiconductor memory device 600.

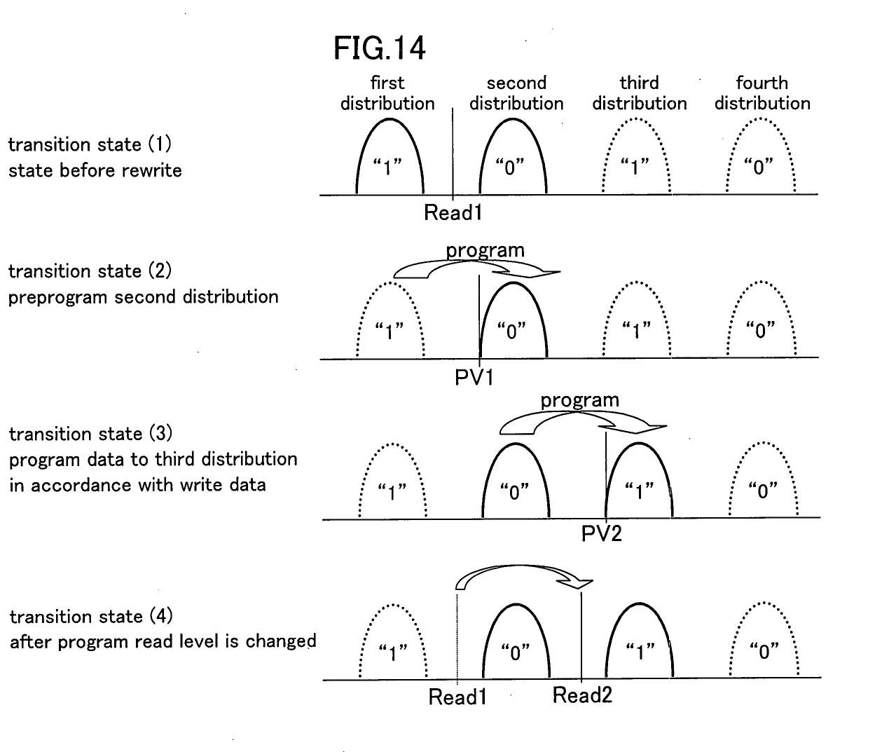

In the non-volatile semiconductor memory device 600, data ‘0’ and data ‘1’ are alternately assigned to four threshold voltage distributions, i.e., a first distribution to a fourth distribution. For example, in a transition state (1) of FIG. 14, the first distribution means data ‘1’, and the second distribution means data ‘0’.

During a read operation in the transition state (1), information indicating the determination level Read1 is set as read determination level information in the sector unit determination level storing circuit 13. The data reversal switching circuit 21 is set by the program sequence control circuit 30 to be in a mode in which the output data of the sense amplifier 3 is directly output. Thereby, using the sense amplifier 3, data in the first distribution state is read as data ‘1’, and data in the second distribution state is read as data ‘0’. The output data read out by the sense amplifier 3 is latched via the data reversal switching circuit 21 into the output data latch 4. Thereafter, the output data latched by the output data latch 4 is output via the output data switching circuit 5 to the output Dout.

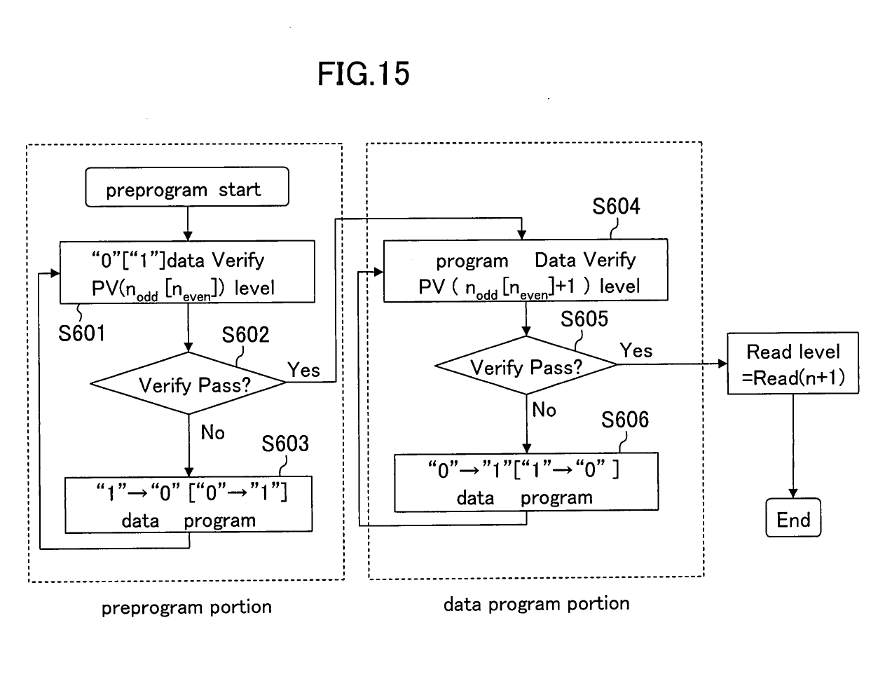

A data write operation is performed by a process indicated by a flowchart of FIG. 15. As illustrated in FIG. 15, the write operation is composed of two steps: a preprogram operation for temporarily set random data to be in a predetermined state; and a data program operation. A process of each step will be hereinafter described.

(Step S601)

As illustrated in a transition state (2) of FIG. 14, during a preprogram operation, the program sequence control circuit 30 sets a write verify level (specifically, the output voltage of the voltage control circuit 15) to be a determination level PV1 via the determination level control circuit 14. The determination level PV1 is a voltage level for determining a distribution state during a program verify operation. The program sequence control circuit 30 also causes the write data latch 8 to latch data ‘0’.

On the other hand, the input data switching circuit 20 inputs data ‘0’ to the verify circuit 7. The verify circuit 7 compares data ‘0’ with output data of the output data switching circuit 5 to verify whether or not the output data of the output data switching circuit 5 is data ‘1’.

(Step S602)

When a comparison result signal from the verify circuit 7 is a FALSE signal, the circuit operation goes to a process of step S603. When the comparison result signal is a TRUE signal, the circuit operation goes to a process of step S604.

(Step S603)

The write circuit 9 writes data ‘0’ (preprogram).

As described above, by repeatedly performing the processes of steps S601 to S603, all memory cells in a sector are caused to be in the second distribution state.

After all pieces of data are temporarily set to be in the second distribution state, a data write operation (data program) of steps S604 to S606 is performed.

(Step S604)

As illustrated in a transition state (3) of FIG. 14, during a preprogram operation, the program sequence control circuit 30 sets the output voltage of the voltage control circuit 15 to be PV2. The program sequence control circuit 30 also sets the data reversal switching circuit 21 to be in a mode in which data is reversed before being output. Thereby, the second distribution means data ‘0’, and the third distribution means data ‘1’.

The input data switching circuit 20 is switched by the program sequence control circuit 30 so as to output the output data of the input data latch 6 to the verify circuit 7. Thereby, the verify circuit 7 verifies the output data of the input data latch 6 and the output data of the output data switching circuit 5.

(Step S605)

When the comparison result signal from the verify circuit 7 is a FALSE signal, the circuit operation goes to a process of step S606. When the comparison result signal is a TRUE signal, the process is ended.

(Step S606)

A write operation is performed by the write circuit 9 with respect to a memory cell which is detected by a verify operation and into which data ‘1’ is to be written, after data ‘1’ is stored into the write data latch 8.

When the data thus written is read out, the read determination level information stored in the sector unit determination level storing circuit 13 is changed from information indicating the determination level Read1 to information indicating the determination level Read2. The data reversal switching circuit 21 is set by the program sequence control circuit 30 to be in a mode in which data is reversed before being output.

Also, during the next write operation, data is stored, where the third distribution corresponds to data ‘1’ and the fourth distribution corresponds to data ‘0’. In this case, the data reversal switching circuit 21 is set by the program sequence control circuit 30 to be in a mode in which the output data of the sense amplifier 3 is directly output. Also, the read determination level is set to be the determination level Read3 (see FIG. 11).

As described above, according to this embodiment, a read operation and a verify operation can be performed without particularly knowing which of the Vt distributions corresponds to data ‘0’ as in the non-volatile semiconductor memory device 400 of Embodiment 4. Therefore, the used distribution position storing area 16 and the monitor bit 17 are no longer required, so that a control during a write operation is easily performed, and at the same time, the area of the non-volatile semiconductor memory device can be reduced.

### Embodiment 7 of the Invention

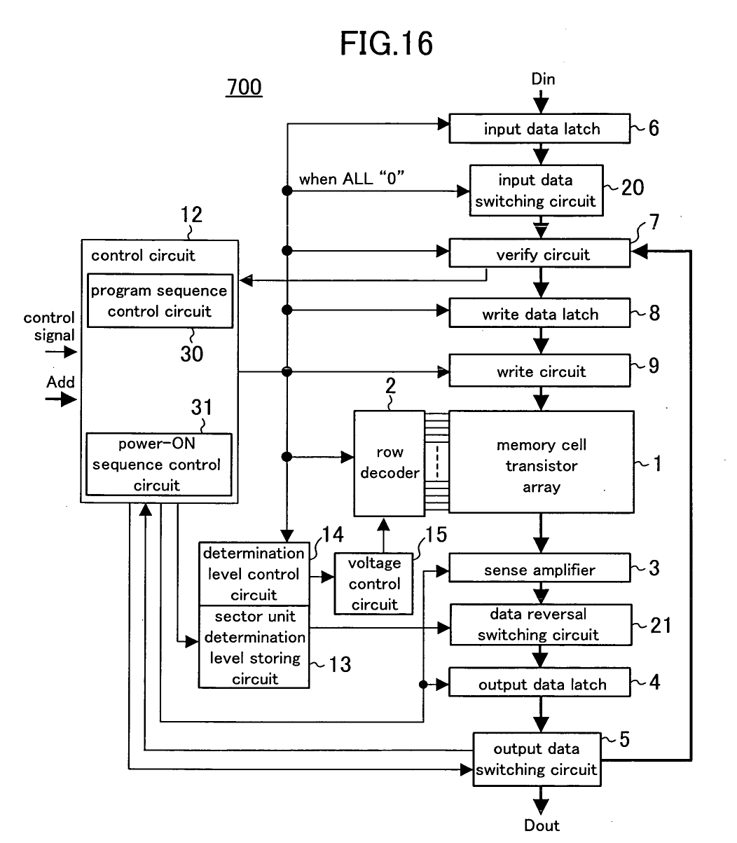

FIG. 16 is a block diagram illustrating a configuration of a non-volatile semiconductor memory device 700 according to Embodiment 7 of the present invention. As illustrated in FIG. 16, the non-volatile semiconductor memory device 700 has the same configuration as that of the non-volatile semiconductor memory device 600, except that a power-ON sequence control circuit 31 is added.

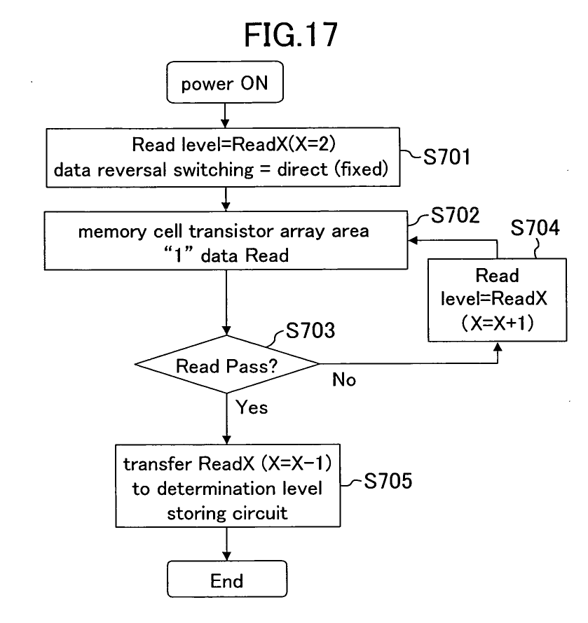

The power-ON sequence control circuit 31 determines a read determination level when power is turned ON. Specifically, the power-ON sequence control circuit 31 performs a control indicated by a flowchart of FIG. 17. A process of each step will be hereinafter described.

(Step S701)

The power-ON sequence control circuit 31, when detecting power-ON, controls the determination level control circuit 14 to set a read determination level to be the determination level Read2. The power-ON sequence control circuit 31 also sets the data reversal switching circuit 21 to be in a direct mode (no-reversal mode).

(Step S702)

Next, the power-ON sequence control circuit 31 controls and causes the verify circuit 7 to perform a verify operation to try to read data ‘1’ from the memory cell transistor array 1.

(Step S703)

A PASS/FAIL test of the result of the verification is performed. When data ‘1’ has not been read out from the memory cell transistor array 1, the circuit operation goes to a process of step S704. When data ‘1’ has been read out, the circuit operation goes to a process of step S705.

(Step S704)

The read determination level is reset to be an immediately higher read determination level (e.g., the determination level Read3 if the current read determination level is the determination level Read2). Thereafter, the circuit operation goes to a process of step S702.

(Step S705)

Regarding the read determination level, read determination level information indicating an immediately lower read determination level (e.g., the determination level Read1 if the current read determination level is the determination level Read2) is transferred and stored into the sector unit determination level storing circuit 13.

According to the non-volatile semiconductor memory device 700, since the read determination level is automatically set after power is turned ON, an effort to select a read level is eliminated. Therefore, the user convenience is improved.

### Embodiment 8 of the Invention

An example which can perform a write operation at a higher rate than those of the non-volatile semiconductor memory device 600 and the like, will be described.

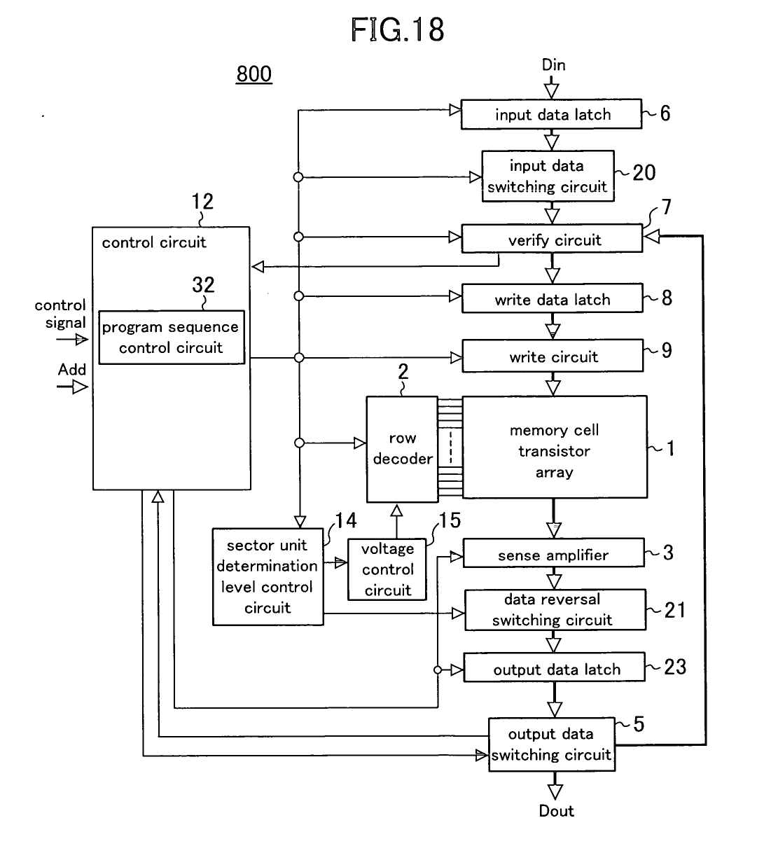

FIG. 18 is a block diagram illustrating a configuration of a non-volatile semiconductor memory device 800 according to Embodiment 8 of the present invention. The non-volatile semiconductor memory device 800 has the same configuration as that of the non-volatile semiconductor memory device 600, except that the sector unit determination level storing circuit 13 of Embodiment 6 is removed, and an output data latch 23 is provided instead of the output data latch 4.

The output data latch 23 latches only data which is selected, depending on a read determination level, of pieces of data output from the data reversal switching circuit 21, and holds data which is once latched until the next verify operation is performed.

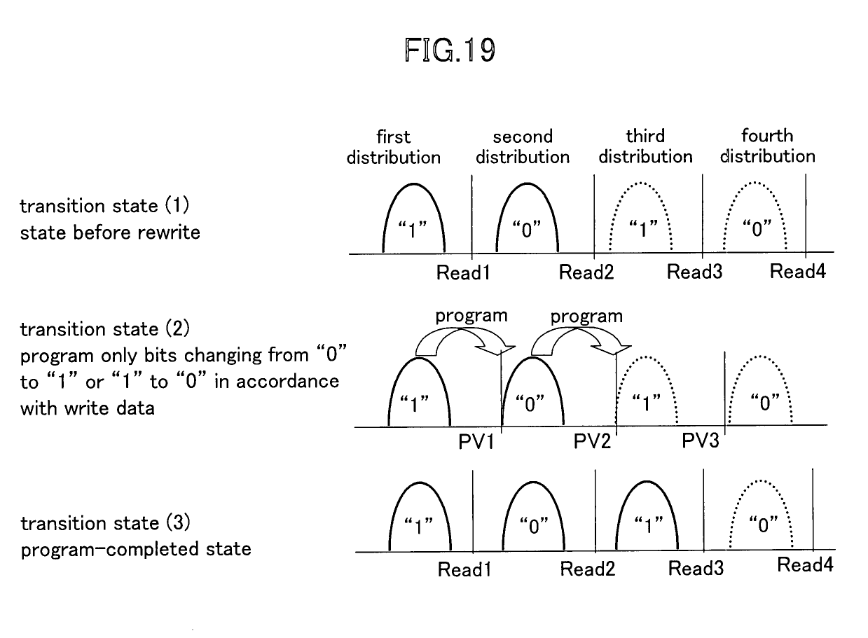

Also in the non-volatile semiconductor memory device 800, data ‘0’ and data ‘1’ are alternately assigned to four threshold voltage distributions (i.e., a first distribution to a fourth distribution). For example, in a transition state (1) of FIG. 19, the first distribution means data ‘1’, and data ‘0’ means the second distribution.

Regarding a read operation in the transition state (1), data is read out from the memory cell transistor array 1 using the sense amplifier 3 a plurality of times, where there are a plurality of read determination levels (i.e., a determination level Read1, a determination level Read2, a determination level Read3, and a determination level Read4). The read data is latched by the output data latch 23, the data of the first distribution is output as data ‘1’, and the data of the second distribution is output as data ‘0’.

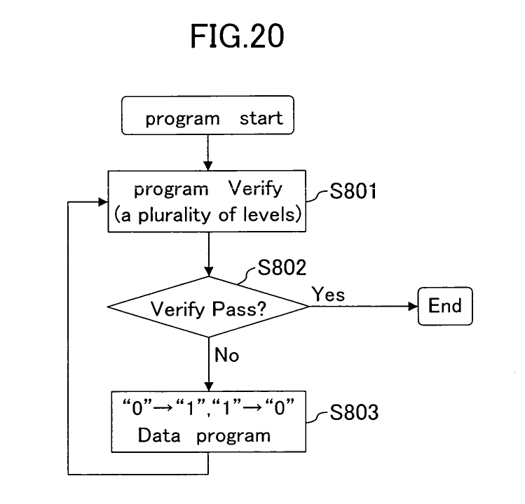

Also, in the non-volatile semiconductor memory device 800, a program sequence control circuit 32 controls a flow of FIG. 20 to perform a data write operation.

In the write operation, as illustrated in FIG. 19, a write verify level is set to be PV1, PV2, PV3, or PV4. As expected value data, data of the input data latch 6 is input to the verify circuit 7 by the input data switching circuit 20.

(Step S801)

The program sequence control circuit 32 controls the verify circuit 7 so that the verify circuit 7 performs a verify operation at a plurality of verify levels to check a memory cell which goes from the first distribution state (data ‘1’) to data ‘0’, and a memory cell which goes from the second distribution state (data ‘0’) to data ‘1’.

(Step S802)

When a comparison result signal from the verify circuit 7 is a FALSE signal, the circuit operation goes to step S803. When the comparison result signal is a TRUE signal, the process is ended.

(Step S803)

In this step, data to be written into a memory cell in which data is changed is latched by the write data latch 8, and is written by the write circuit 9.

By performing the processes of steps S801 to S803, data ‘1’ of the first threshold distribution in which data is changed is programmed into data ‘0’ of the second threshold distribution, and data ‘0’ of the second threshold distribution is programmed into data ‘1’ of the third threshold distribution.

As described above, according to this embodiment, it is not necessary to perform a write operation with respect to a memory cell which is not changed, so that the number of write bits is reduced. Therefore, a write operation can be performed at a higher rate than those of the non-volatile semiconductor memory device 600 and the like.

### Embodiment 9 of the Invention

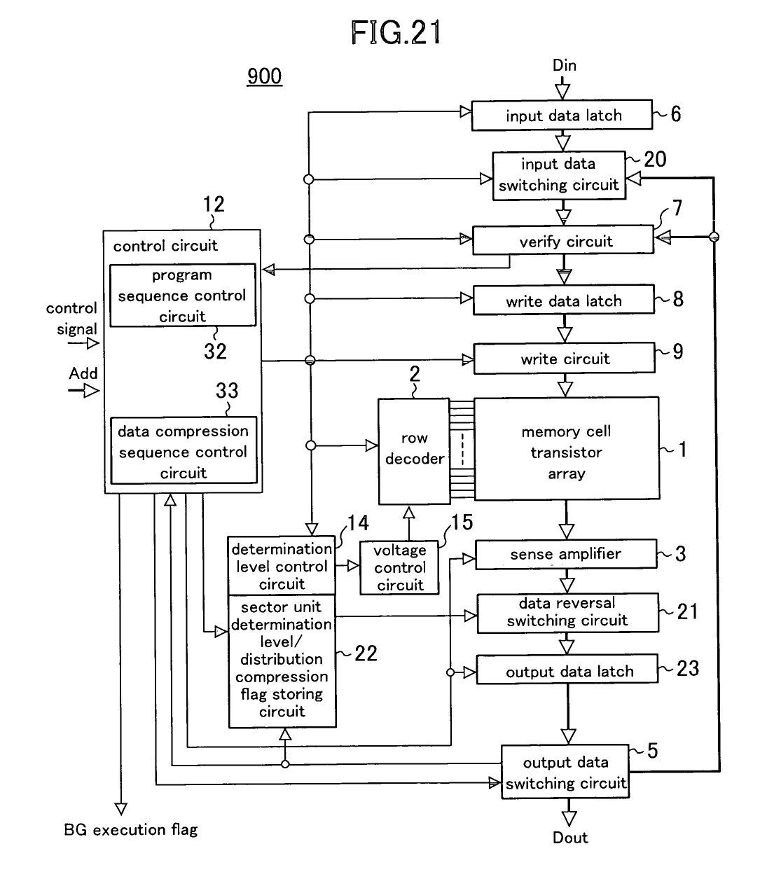

FIG. 21 is a block diagram illustrating a configuration of a non-volatile semiconductor memory device 900 according to Embodiment 9 of the present invention. As illustrated in FIG. 21, the non-volatile semiconductor memory device 900 has the same configuration as that of the non-volatile semiconductor memory device 800, except that a data compression sequence control circuit 33 is added, and a sector-specific determination level/distribution compression flag storing circuit 22 is provided instead of the sector unit determination level storing circuit 13. The non-volatile semiconductor memory device 900 has a mode in which a read operation is performed using a plurality of read determination levels (multi-level read mode), and a mode in which a read operation is performed using a single read determination level (single-level read mode). Also, in order to externally detect a compression executed state (described below) in the background, a background execution flag (denoted as a BG execution flag in FIG. 21) is stored, and a value of the background execution flag is output to a microcomputer (not shown).

The sector-specific determination level/distribution compression flag storing circuit 22 stores a distribution compression flag (described above). The sector-specific determination level/distribution compression flag storing circuit 22 also stores read determination level information.

In this embodiment, the output data latch 23 has: a mode in which, when data is read out using a plurality of read determination levels, the output data latch 23 latches only data which is selected, depending on a read level, of pieces of data output from the data reversal switching circuit 21, and holds data which is once latched until the next verify operation is performed; and a mode in which, when data is read out using a single level, the output data latch 23 holds data from the data reversal switching circuit 21 until the next verify operation is performed.

The data compression sequence control circuit 33 reduces (compresses) the number of used threshold voltage distributions from a state in which three or more threshold voltage distributions are used for data storage to a state in which two threshold voltage distributions are used for data storage. The compression by the data compression sequence control circuit 33 is performed after a data rewrite operation is finished and when an operation is not performed (i.e., in the background). The distribution compression flag stored in the sector-specific determination level/distribution compression flag storing circuit 22 is a flag indicating whether or not the compression of the number of threshold voltage distributions has been performed. When the distribution compression flag indicates data ‘0’, the compression has been completed. When the distribution compression flag indicates data ‘1’, the compression has not been completed. Note that, for the sake of convenience, regarding a value of each flag, data ‘1’ is also referred to as ‘L’ (LOW level), and data ‘0’ is also referred to as ‘H’ (HIGH level).

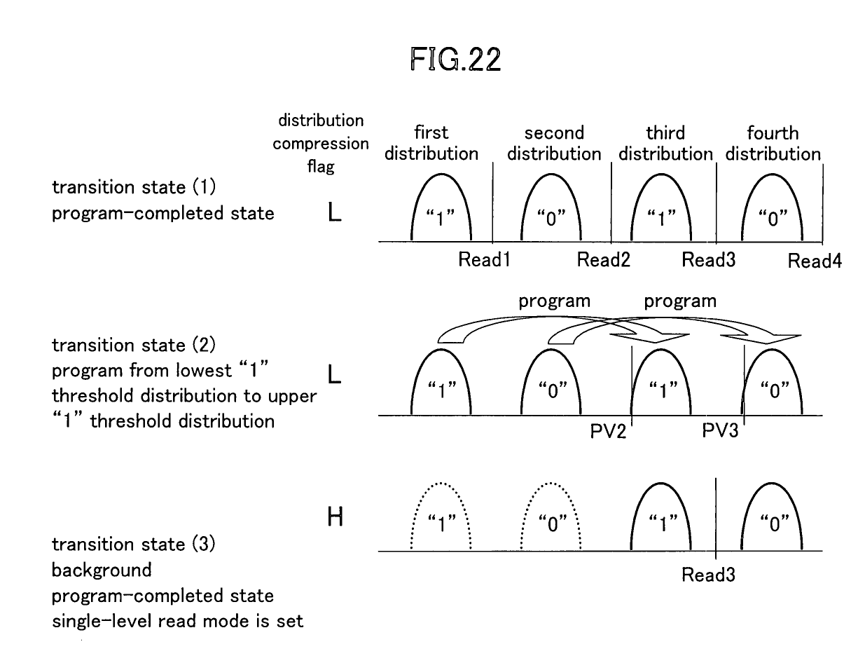

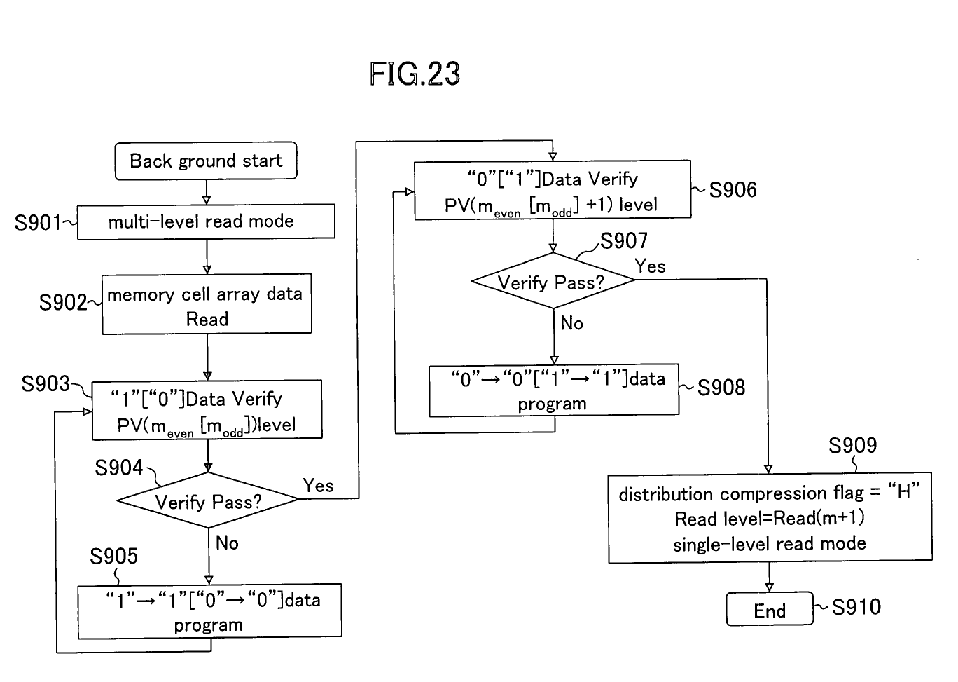

Hereinafter, an operation of the non-volatile semiconductor memory device 900 will be described in detail with reference to FIGS. 22 and 23.

FIG. 22 is a diagram illustrating transition states of threshold voltage distributions when a compression operation is performed in the background, in the non-volatile semiconductor memory device 900. FIG. 23 is a flowchart of an operation of compressing the number of threshold voltage distributions in the background. A process of each step is controlled by the data compression sequence control circuit 33.

In a transition state (1) of FIG. 22, a first distribution is used to store data ‘1’, a second distribution is used to store data ‘0’, a third distribution is used to store data ‘1’, and a fourth distribution is used to store data ‘0’.

During a read operation, data is read out from the memory cell transistor array 1 by the sense amplifier 3 using a plurality of read determination levels (i.e., a determination level Read1, a determination level Read2, a determination level Read3, and a determination level Read4). The data thus read out is latched by the output data latch 23, and data of the first distribution is output as data ‘1’, data of the second distribution is output as data ‘0’, data of the third threshold voltage distribution is output as data ‘1’, and data of the fourth threshold voltage distribution is output as data ‘0’.

In a data compression write operation in the background, data ‘1’ and data ‘0’ of the first distribution and the second threshold voltage distribution, respectively, which are located at lower positions, are programmed into data ‘1’ and data ‘0’ of the third distribution and the fourth threshold voltage distribution, respectively, which are located at upper positions (see a transition state (2) of FIG. 22).

As illustrated in FIG. 23, a read operation is performed using a plurality of levels in order to check a current written state in steps S901 and S902, and the result is input as expected value data via the output data latch 23, the output data switching circuit 5, and the input data switching circuit 20 to the verify circuit 7. Thereafter, in step S903, a write verify level is set to be the level PV2, and a verify operation is performed, so that it is checked that the first distribution has data ‘1’. Data ‘1’ detected by the verify operation is stored in the write data latch 8.

Thereafter, in step S905, data ‘1’ is programmed by the write circuit 9 in accordance with the data latched by the write data latch 8. In step S904, step S903 is repeatedly performed until a program verify operation passes.

After the write operation of data ‘1’ has passed, a verify level is set to be the level PV3. Thereafter, a write operation is similarly performed with respect to data ‘0’ in steps S906, S907 and S908.

After the end of the write operation, in step S909, the distribution compression flag of the sector-specific determination level/distribution compression flag storing circuit 22 is set to be data ‘0’ (‘H’). Thereby, the output data latch 23 is set to be in the single-level read mode. Also, the read determination level is set to be the determination level Read3, and a read operation is performed using only a single level (see a transition state (3) of FIG. 22).

As described above, in the non-volatile semiconductor memory device 900, the number of used threshold voltage distributions is compressed in the background from the state in which three or more threshold voltage distributions are used for data storage to the state in which two threshold voltage distributions are used for data storage. Therefore, the number of times of read during a read operation can be reduced, thereby making it possible to provide a non-volatile semiconductor memory device in which a penalty in a read operation is eliminated without deteriorating a write speed.

### Embodiment 10 of the Invention

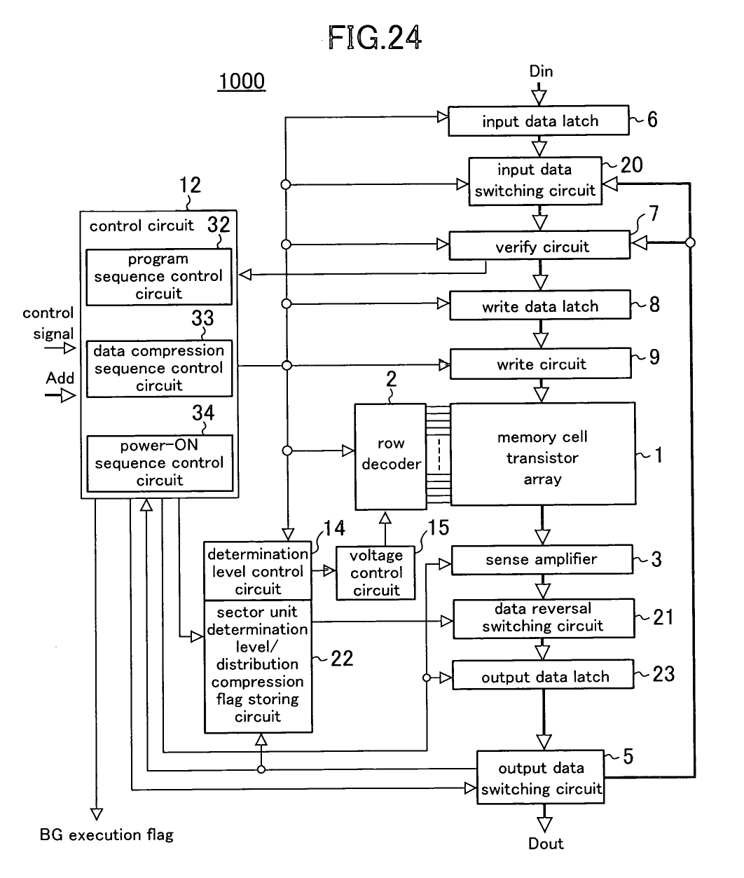

FIG. 24 is a block diagram illustrating a configuration of a non-volatile semiconductor memory device 1000 according to Embodiment 10 of the present invention. As illustrated in FIG. 24, the non-volatile semiconductor memory device 1000 has the same configuration as that of the non-volatile semiconductor memory device 900, except that a power-ON sequence control circuit 34 is added.

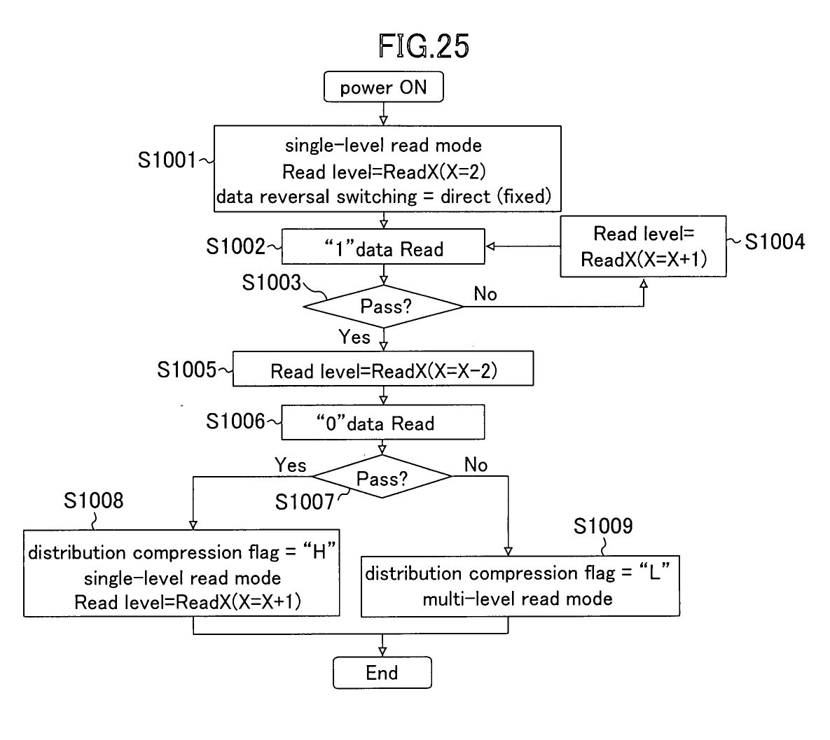

The power-ON sequence control circuit 34, when power is turned ON, sets a read mode, and determines whether or not compression of used distributions has been completed. Specifically, the power-ON sequence control circuit 34 performs a control which is indicated by a flowchart of FIG. 25.

After power is turned ON, in step S1001, the power-ON sequence control circuit 34 sets a read determination level to be the level Read2. Thereafter, in step S1002, a read operation is performed with respect to data ‘1’.

When it is determined that the read operation has failed in step S1003, the read determination level is shifted to the level Read3 in step S1004, and step S1002 is repeatedly performed until the read operation passes.

After the read operation passes in step S1003, the current read determination level is changed to a read determination level which is lower by two steps than the current read determination level in step S1005.

In step S1006, a read operation is performed with respect to data ‘0’. In step S1007, when it is determined that the read operation has passed, it is determined that compression of the number of used distributions has been completed.

In step S1008, the distribution compression flag is set to be data ‘0’ (‘H’), and the read mode is set to be the single-level read mode. Also, a read determination level which is higher by one step than the current read determination level is set into the sector-specific determination level/distribution compression flag storing circuit 22.

In step S1007, when it is determined that the read operation has failed, it is determined that the number of used distributions is not yet compressed. In this case, in step S1009, the distribution compression flag is set to be data ‘1’ (‘L’), and the read mode is set to be the multi-level read mode.

As described above, according to the non-volatile semiconductor memory device 1000, by performing a read operation with respect to the memory cell transistor array 1 when power is turned ON, it can be easily determined whether or not a background process has been finished. In other words, a read mode can be automatically selected, so that an effort to select a read mode is eliminated, resulting in an improvement in the user convenience.

### Embodiment 11 of the Invention

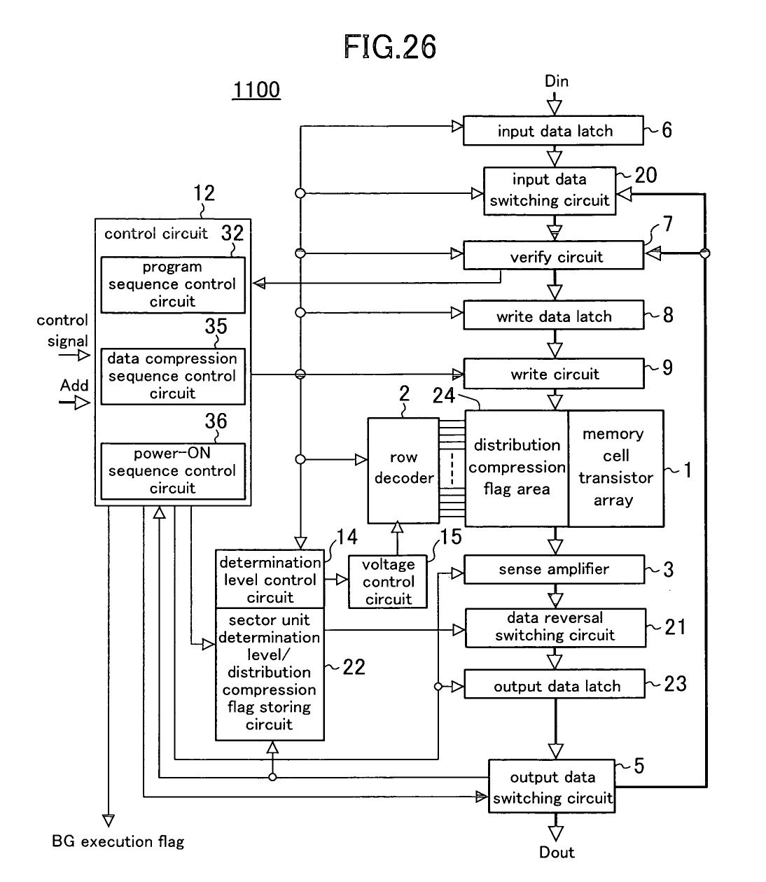

FIG. 26 is a block diagram illustrating a configuration of a non-volatile semiconductor memory device 1100 according to Embodiment 11 of the present invention. As illustrated in FIG. 26, the non-volatile semiconductor memory device 1100 has the same configuration as that of the non-volatile semiconductor memory device 1000, except that a distribution compression flag area 24 is added, a data compression sequence control circuit 35 is provided instead of the data compression sequence control circuit 33, and a power-ON sequence control circuit 36 is provided instead of the power-ON sequence control circuit 34.

The distribution compression flag area 24 is a non-volatile memory area which is similar to the memory cell of the memory cell transistor array 1. In the distribution compression flag area 24, distribution compression information indicating whether or not the number of threshold voltage distributions has been compressed, is stored as a distribution compression flag. In this embodiment, when the distribution compression flag indicates data ‘0’ (‘H’), it is meant that the number of threshold voltage distributions has been compressed. When the distribution compression flag indicates data ‘1’ (‘L’), it is meant that the number of threshold voltage distributions has not been compressed. Also, information indicating a read determination level is written in the distribution compression flag area 24.

The data compression sequence control circuit 35 controls the operation of compressing the number of threshold voltage distributions.

The power-ON sequence control circuit 36, when power is turned ON, selects a read mode using the information indicating whether or not the number of threshold voltage distributions has been compressed and the information indicating a read determination level, which are stored in the sector-specific determination level/distribution compression flag storing circuit 22.

Also, in the non-volatile semiconductor memory device 1100, the sector-specific determination level/distribution compression flag storing circuit 22 stores information read out from the distribution compression flag area, as the distribution compression flag.

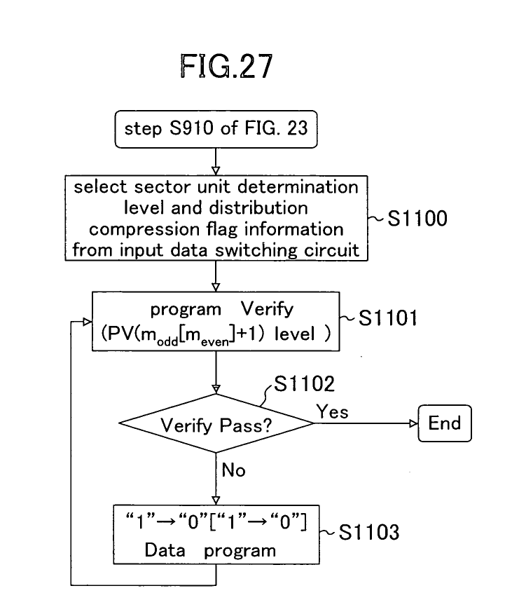

FIG. 27 is a flowchart of the operation of compressing the number of threshold voltage distributions. A process of each step is controlled by the data compression sequence control circuit 35.

During a data write operation, as in the non-volatile semiconductor memory device 900 of Embodiment 9, after the number of threshold voltage distributions is compressed in the background, the read determination level of the sector-specific determination level/distribution compression flag storing circuit 22 and information indicated by the distribution compression flag are input to the input data switching circuit 20 to generate an expected value in step S1100. In step S11 01, a verify operation is performed. Data is written into the distribution compression flag area 24 in S1103 until determination in step S1102 passes.

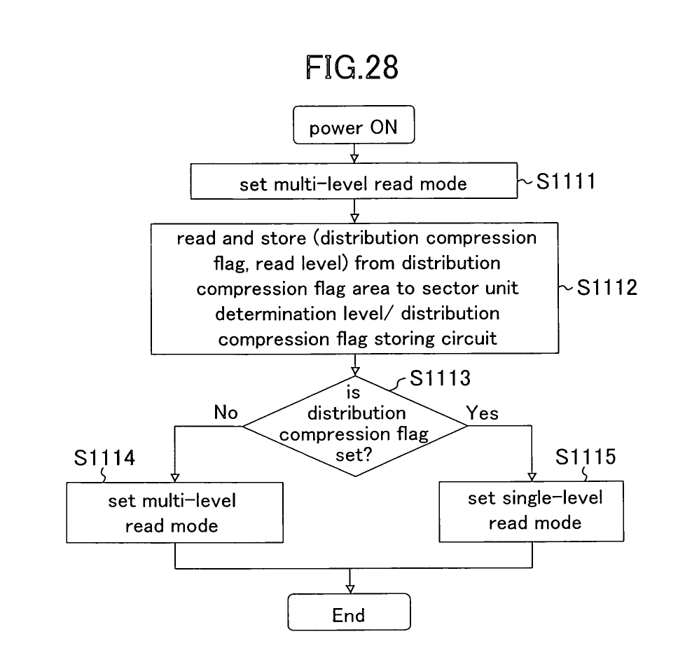

FIG. 28 is a flowchart of a control of the power-ON sequence control circuit 36 when power is turned ON.

After power is turned ON, in step S1111, a read determination level is set to be the determination level Read 1, and thereafter, in step S1112, the read determination level and the distribution compression information written in the distribution compression flag area 24 are read out, and are stored into the sector-specific determination level/distribution compression flag storing circuit 22.

In step S1113, the distribution compression flag is checked. When it is determined that the distribution compression flag indicates data ‘1’ (‘L’), the circuit operation goes to a process of step S1114, a read mode is set to be the multi-level read mode, and the next read operation is performed.

Also, in step S1113, when it is determined that the distribution compression flag indicates data ‘0’ (‘H’), the circuit operation goes to a process of step S1115, the read mode is set to be the single-level read mode, and the next read operation is performed.

According to the non-volatile semiconductor memory device 1100, when power is turned ON, information stored in the distribution compression flag area 24 is read out, and the read information is transferred to the sector-specific determination level/distribution compression flag storing circuit 22, thereby making it possible to easily determine whether or not the background process has been finished. In other words, a read mode can be automatically selected, so that an effort to select a read mode is eliminated, resulting in an improvement in the user convenience.

### Embodiment 12 of the Invention

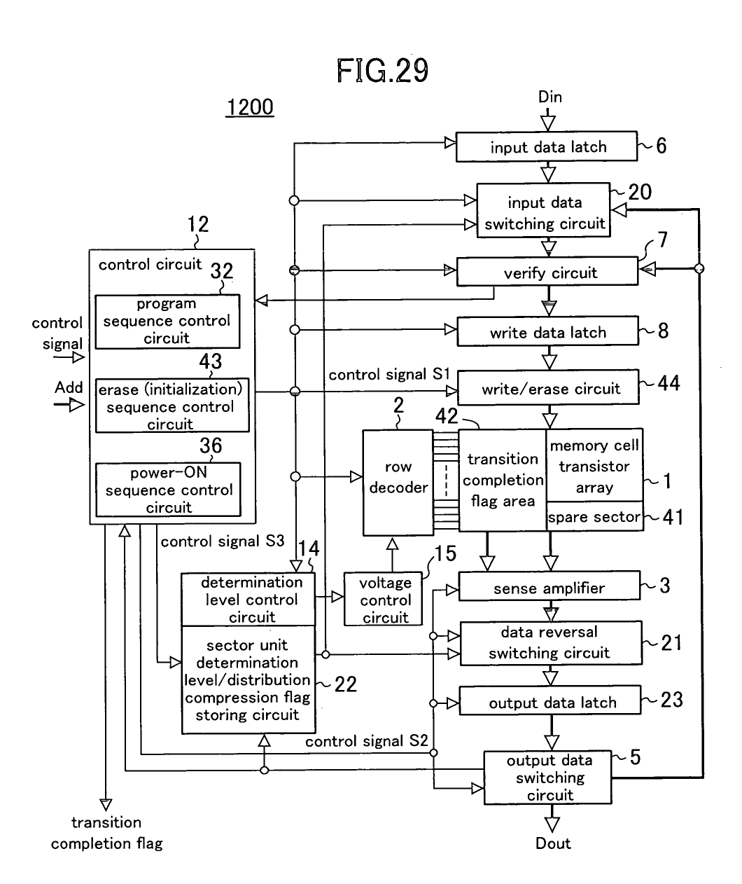

FIG. 29 is a block diagram illustrating a configuration of a non-volatile semiconductor memory device 1200 according to Embodiment 12 of the present invention. As illustrated in FIG. 29, the non-volatile semiconductor memory device 1200 has the same configuration as that of the non-volatile semiconductor memory device 1100, except that a spare sector 41 and an initialization sequence control circuit 43 are added, a transition completion flag area 42 is provided instead of the distribution compression flag area 24, and a write/erase circuit 44 is provided instead of the write circuit 9.

The spare sector 41 is composed of a plurality of non-volatile memory cells which are similar to those of the memory cell transistor array 1. Data (data ‘0’and ‘1’) recorded in a sector of the memory cell transistor array 1 is transferred into the spare sector 41, so that a backup of data in a predetermined sector of the memory cell transistor array 1 is temporarily saved.

The transition completion flag area 42 is composed of a plurality of non-volatile memory cells which are similar to those of the memory cell transistor array 1. In the transition completion flag area 42, information indicating, for each sector, whether or not a Vt distribution has been transitioned to the maximum Vt distribution level after a plurality of times of writing data ‘0’ or ‘1’ (transition completion information) is stored as a transition completion flag. In this embodiment, when the transition completion flag indicates data ‘0’ (‘H’), it is meant that the Vt distribution has reached the maximum Vt distribution level, and when the transition completion flag indicates data ‘1’ (‘L’), it is meant that the Vt distribution has not reached the maximum Vt distribution level. Note that the value of the transition completion flag area 42 is output via the control circuit 12 to the microcomputer (not shown) so that the microcomputer can detect that the Vt distribution level of each sector of the memory cell transistor array 1 has reached the maximum Vt distribution level.

The initialization sequence control circuit 43 controls an operation of initializing a memory cell (erase operation). Specifically, the initialization sequence control circuit 43 controls each circuit block of the memory using the spare sector 41 so that at least a pair of data ‘0’ and data ‘1’ are collected and initialized (written back) into the lowest ‘0’ and ‘1’ data distributions without impairing address matching.

The write/erase circuit 44 performs a data erase operation and a data write operation with respect to memory cells in units of a sector in accordance with a control signal S1 from the control circuit 12. During the data erase operation, specifically, a voltage of 6 V is applied via bit lines to drain terminals of all memory cells of a sector to be erased. In this case, source terminals of all the memory cells of the sector to be erased have high impedance. As a result, electrons are extracted from the electric charge accumulation portions of all the memory cells of the sector to be erased, which are connected to a word line to which a negative voltage is applied and to whose drain terminals a voltage of 6 V is applied via the bit lines, to perform an erase operation, so that the threshold of the memory cell is reduced in a negative direction.

Hereinafter, an operation of the non-volatile semiconductor memory device 1200 will be described.

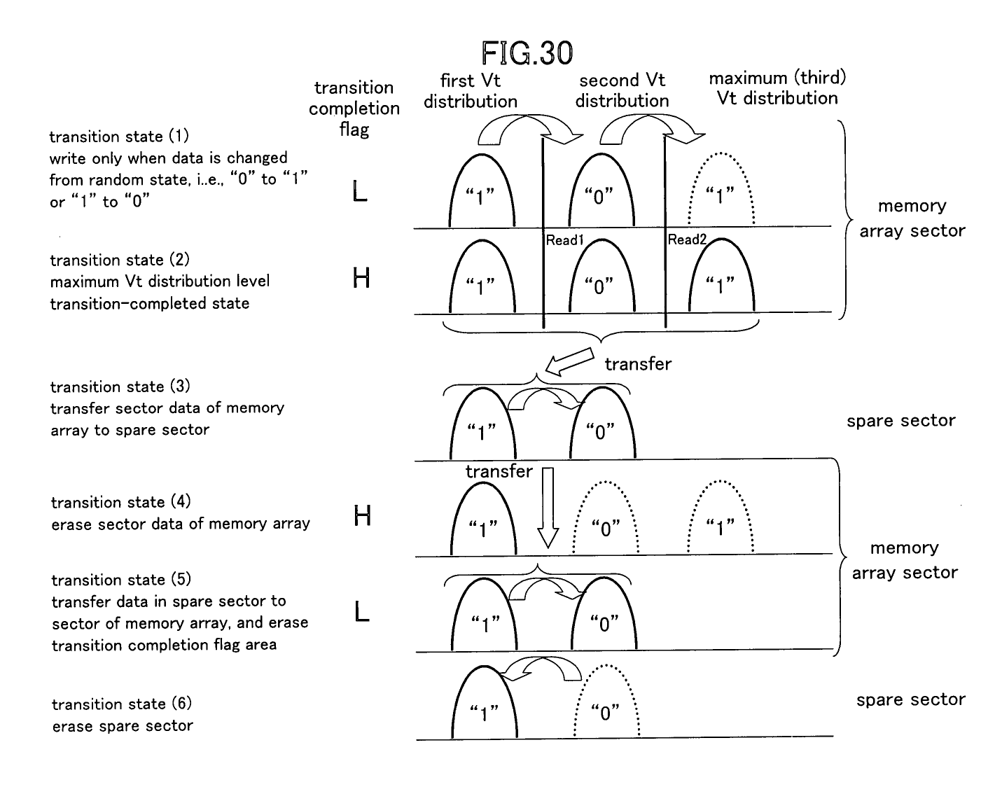

FIG. 30 illustrates transitions of Vt distribution states when a sector whose Vt distribution has been transitioned to the maximum Vt distribution level is rewritten (initialized) into data having the lowest Vt value distribution.

When a sector in the memory cell transistor array 1 is in a random data distribution state in which a first distribution and a second distribution are used (a transition state (1) of FIG. 30), a write operation is performed with respect to only a memory cell(s) in which data is changed from ‘0’ to ‘1’ or from ‘1’ to ‘0’.

When the maximum distribution level (third distribution) is occupied, the control circuit 12 writes transition completion information (in this case, data ‘0’ (‘H’)) into the transition completion flag area 42 (see a transition state (2) of FIG. 30). Next, data of the transition completion flag area 42 corresponding to each sector is read out. When at least one piece of data ‘0’ (‘H’) has been detected by the control circuit 12, the control circuit 12 outputs data ‘0’ (‘H’) as a transition completion flag to the sector-specific determination level/distribution compression flag storing circuit 22. When all pieces of data have been detected as data ‘1’ (‘L’), data ‘1’ (‘L’) is output as a transition completion flag to the sector-specific determination level/distribution compression flag storing circuit 22. The control circuit 12 also outputs the transition completion information to a microcomputer (not shown). Note that the read and write operations of the transition completion flag area 42 are the same as those of the memory cell transistor array 1 in Embodiment 11 and will not be described.

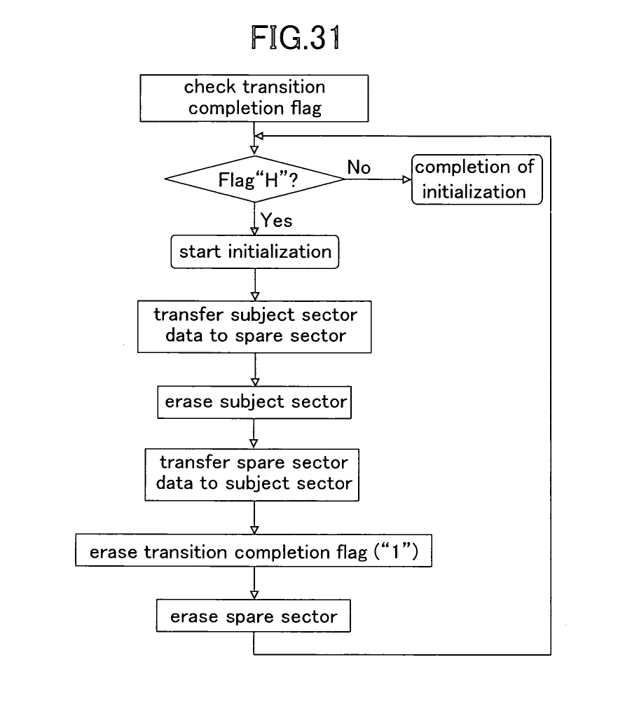

Next, as illustrated in FIG. 31, the microcomputer (not shown) checks a transition completion flag, and when the transition completion flag indicates data ‘1’ (‘L’), none of the sectors has reached the maximum distribution level, so that the microcomputer does not give an instruction to execute an initialization operation. When the transition completion flag indicates data ‘0’ (‘H’), the microcomputer gives an instruction to execute an initialization operation with respect to at least one sector which needs to be initialized.

When initialization is started in accordance with the instruction from the microcomputer, the initialization sequence control circuit 43 controls the initialization operation in accordance with the initialization sequence flow of FIG. 31.

Initially, all pieces of data ‘0’ and ‘1’ recorded in a sector to be initialized are read out, the read data is transferred to the input data switching circuit 20 by the output data switching circuit 5, and the input data switching circuit 20 causes, via the verify circuit 7, the write data latch 8 to latch the transferred data.

Next, the latched data is written into the spare sector 41. Specifically, the data in the sector to be initialized is transferred to the spare sector 41 (see a transition state (3) of FIG. 30). The write operation of the spare sector 41 is the same as that of Embodiment 11 and will not be described.

Next, data is erased from the sector which is being initialized, and all pieces bit data are set to be data ‘1’ of the lowest distribution level (see a transition state (4) of FIG. 30).

Here, the erase operation will be specifically described. The determination level control circuit 14, which is controlled by the control circuit 12 which has received a control signal from the microcomputer, controls the voltage control circuit 15. Thereby, the voltage control circuit 15 outputs and supplies a negative voltage of −5 V to the row decoder 2. In this case, the row decoder 2, which is controlled in accordance with the control signal S1 of the control circuit 12, applies a voltage of −5 V via a word line to gate terminals of all the memory cells of the sector to be erased. The write/erase circuit 44, which is controlled in accordance with the control signal S1, applies a voltage of 6 V via bit lines to the drain terminals of all the memory cells of the sector to be erased. In this case, the source terminals of all the memory cells of the sector to be erased have high impedance. As a result, an erase operation is performed with respect to all the memory cells of the sector to be erased, which are connected to a word line to which a negative voltage is applied and to whose drain terminals a voltage pf 6 V is applied via bit lines, whereby electrons are extracted from the electric charge accumulation portions, so that the threshold of the memory cell is reduced in the negative direction. After the erase operation of the sector to be initialized (see the transition state (4) of FIG. 30), all pieces of data ‘0’ and ‘1’ recorded in the spare sector 41 are read out, and the read data is transferred to the input data switching circuit 20 by the output data switching circuit 5. Thereafter, the input data switching circuit 20 causes, via the verify circuit 7, the write data latch 8 to latch the transferred data. Here, the data read operation of the spare sector 41 is the same as that of the memory cell transistor array 1 in Embodiment 11 and will not be described.

Next, the latched data is initialized (written back) as data ‘0’ and ‘1’ of the lowest distribution into a memory array sector which is being initialized. Specifically, the write/erase circuit 44 transfers data in the spare sector 41 to the sector to be initialized (see a transition state (5) of FIG. 30). After the transfer, by performing an operation similar to the sector erase operation of the memory cell transistor array 1, a predetermined bit in the transition completion flag area 42 corresponding to the sector for which the transfer has been completed is erased and reset to be data ‘1’ (‘L’). After the resetting, the spare sector 41 is erased (into a state in which data ‘1’ is stored), and is ready to perform the next initialization operation (see a transition state (6) of FIG. 30).

Next, as illustrated in FIG. 31, the microcomputer (not shown) checks the transition completion flag again. Thereby, the initialization operation is repeatedly performed until the transition completion flag becomes data ‘1’ (‘L’).

According to the non-volatile semiconductor memory device 1200, it is possible for the microcomputer (not shown) to perform an initialization control of a sector. Also, an erase operation is performed only once with respect to writing of data ‘1’ and ‘0’, so that the number of times of an erase operation is reduced as compared to conventional non-volatile semiconductor memory devices in which an erase operation is required every time data ‘1’ and ‘0’ are rewritten. Therefore, the reliability of a memory cell is improved, making it possible to improve the number of times of a write operation of data.

Although it has been described in this embodiment that the number of Vt distribution states is three, a similar effect can be obtained even when N (N: a natural number of 3 or more) Vt distribution states are used.

Also, in this embodiment, when the transition completion flag indicates data ‘0’ (‘H’), the sector is initialized. Alternatively, when the transition completion flag indicates data ‘1’ (‘L’) (i.e., a Vt distribution state before the highest Vt distribution of data ‘1’ to ‘0’ occupies the maximum Vt distribution level), the sector is initialized.

### Embodiment 13 of the Invention

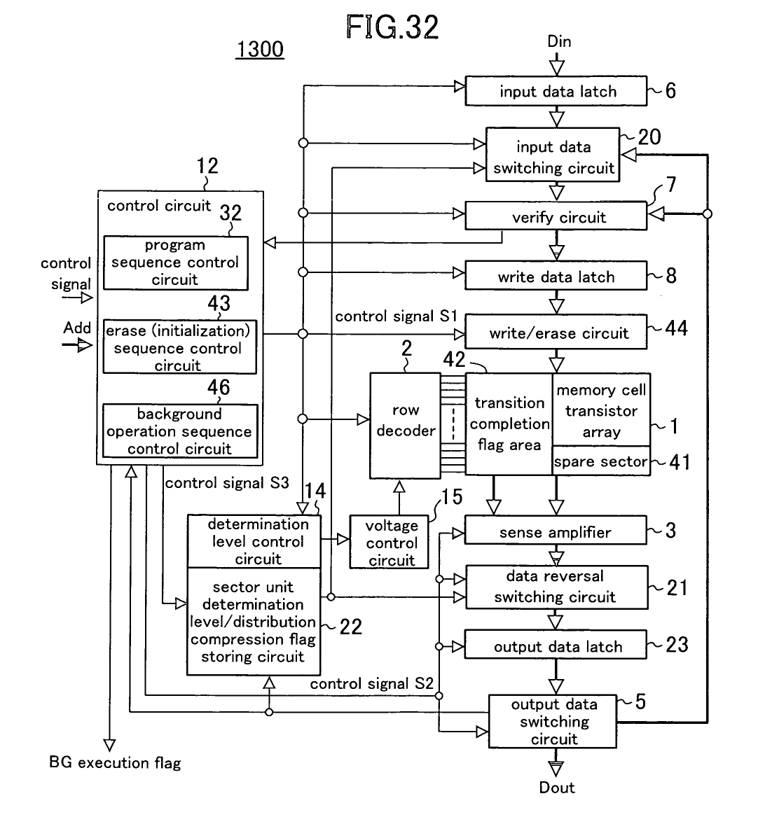

FIG. 32 is a block diagram illustrating a configuration of a non-volatile semiconductor memory device 1300 according to Embodiment 13 of the present invention. As illustrated in FIG. 32, the non-volatile semiconductor memory device 1300 has the same configuration as that of the non-volatile semiconductor memory device 1200, except that a background operation sequence control circuit 46 is provided instead of the power-ON sequence control circuit 36. Also, the non-volatile semiconductor memory device 1300 has a BG execution flag which indicates whether or not an initialization operation of a sector is being executed in the background (BG), and outputs the BG execution flag to a microcomputer (not shown). Thereby, the microcomputer (not shown) can detect whether or not the sector initialization operation is being executed in the background (BG).

During the sector initialization operation, since the non-volatile semiconductor memory device 1300 is in a busy state, the background operation sequence control circuit 46 sets the BG execution flag to be data ‘0’ (‘H’). Also, after the sector initialization operation is finished, the BG execution flag is set to be data ‘1’ (‘L’).

Hereinafter, an operation of the non-volatile semiconductor memory device 1300 will be described.

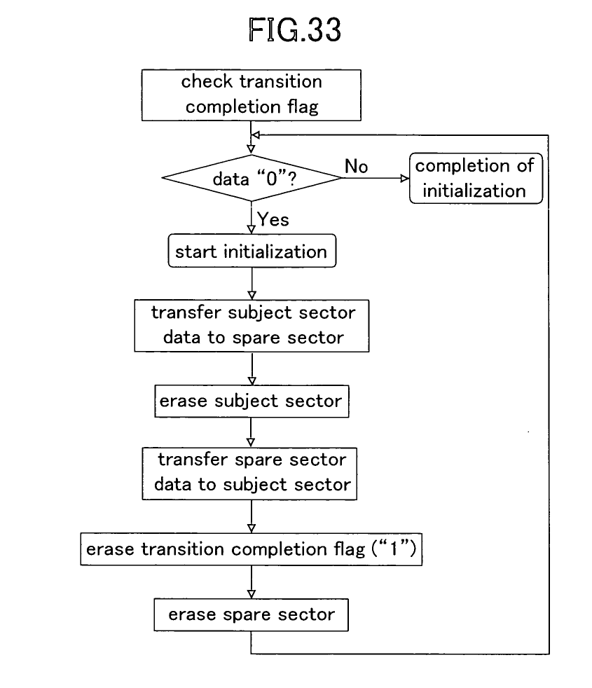

When a control signal is not input from the microcomputer (not shown), the background operation sequence control circuit 46 reads out data from the transition completion flag area 42 via the output data switching circuit 5. When data ‘0’ (‘H’) has been read out from the transition completion flag area 42, there is at least one transition completion sector. In this case, data ‘0’ (‘H’) is output as a BG execution flag so that an initialization operation of a transition completion sector is executed in the background (BG) in accordance with an initialization sequence flow of FIG. 33.

In this case, the non-volatile semiconductor memory device 1300 uses the BG execution flag to notify the microcomputer (not shown) that a control signal cannot be received. After the sector initialization operation in the background (BG) is finished, the background operation sequence control circuit 46 outputs data ‘1’ (‘L’) as a BG execution flag to notify the microcomputer (not shown) that the non-volatile semiconductor memory device 1300 is ready to receive the control signal.

As described above, according to Embodiment 13, an effect similar to that of the non-volatile semiconductor memory device 1200 of Embodiment 12 is obtained. Also, by providing the background operation sequence control circuit 46 and the BG execution flag, a sector initialization operation can be performed during a free time in which a control signal is not input from the microcomputer (not shown), so that an apparent initialization operation is eliminated. In other words, a time required for initialization during a data write operation can be reduced, thereby making it possible to improve the user convenience.

### Embodiment 14 of the Invention

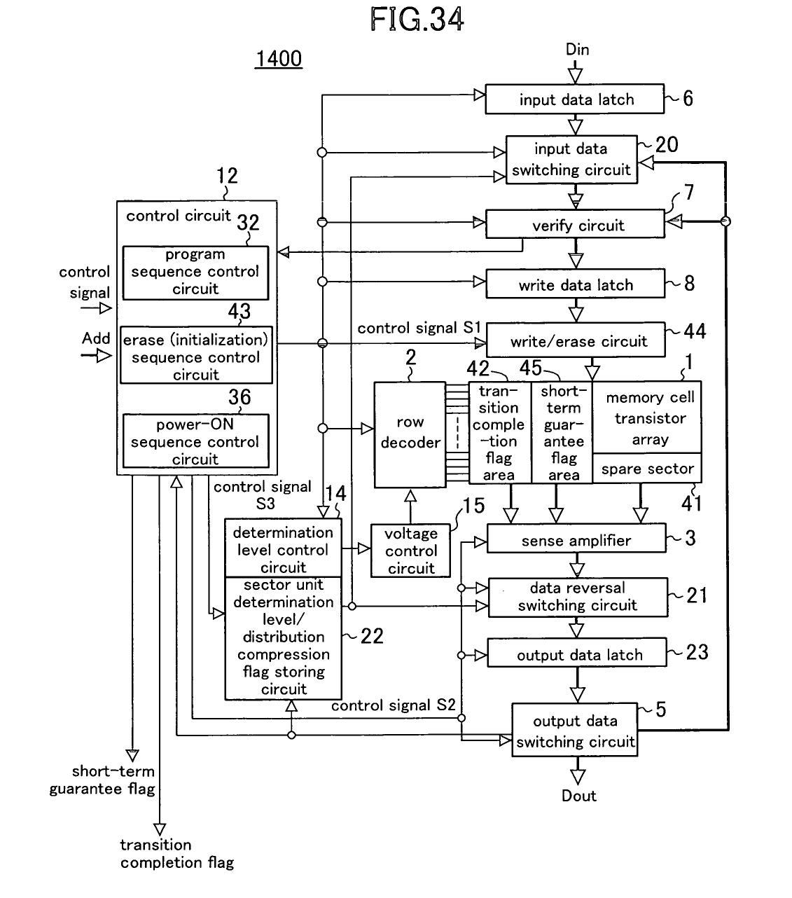

FIG. 34 is a block diagram illustrating a configuration of a non-volatile semiconductor memory device 1400 according to Embodiment 14 of the present invention. As illustrated in FIG. 34, the non-volatile semiconductor memory device 1400 has the same configuration as that of the non-volatile semiconductor memory device 1200, except that a short-term guarantee flag area 45 is added.

The short-term guarantee flag area 45 is composed of non-volatile memory cells as in the memory cell transistor array 1.

Also, in the non-volatile semiconductor memory device 1400, the write/erase circuit 44 is controlled in accordance with the control signal S1 output from the control circuit 12 so that the write/erase circuit 44 is selectively operated in a normal write (long-term guarantee) mode or in a high-rate write (short-term guarantee) mode in which a write operation is performed in a period of time shorter than that of the normal write mode. Specifically, the write/erase circuit 44 sets verify voltages during write operations of data ‘1’ and ‘0’ to be PV1 (=4.5 V) and PV2 (=7.0 V), respectively, in the normal write (long-term guarantee) mode, and PVS1 (=3.3 V) and PVS2 (=5.8 V), respectively, in the high-rate write (short-term guarantee) mode. Note that the determination levels Read1 (=3 V) and Read2 (=5.5 V) are constant no matter whether a write operation is performed in the normal write mode or in the high-rate write mode.

In the high-rate write (short-term guarantee) mode, by narrowing a Vt margin from a long-term guarantee margin to a short-term guarantee margin, an amount of Vt distribution shift during a write operation is reduced, so that a write operation can be performed at a higher rate than that of the normal write operation, while the Vt margin is sacrificed, so that data holding ability is deteriorated, resulting in shorter-term guarantee data than normal.

In the short-term guarantee flag area 45, information indicating whether data is saved in the normal write (long-term guarantee) mode or in the high-rate write (short-term guarantee) mode, in units of a sector, is stored as a short-term guarantee flag.

Also, as illustrated in FIG. 34, the control circuit 12 is controlled in accordance with a control signal to receive the flag information read out from the short-term guarantee flag area 45 via the output data switching circuit 5, and when there is at least one short-term guarantee sector, output the short-term guarantee flag as data ‘0’ (‘H’) so that the microcomputer (not shown) can detect that at least one sector of the memory cell transistor array 1 is written as short-term guarantee data.

Hereinafter, an operation of the non-volatile semiconductor memory device 1400 will be described.

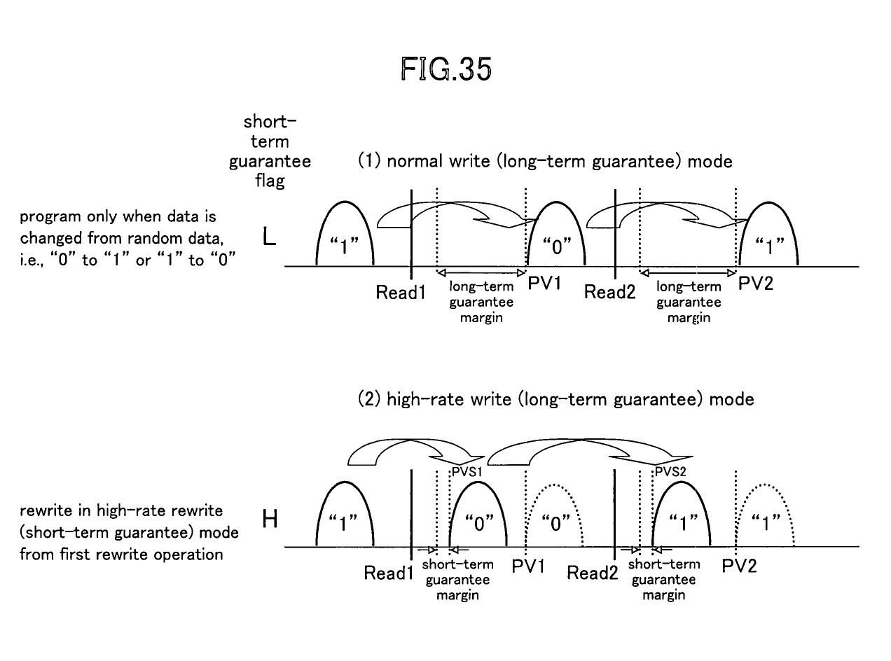

FIG. 35 is a diagram illustrating transitions of Vt distribution states when a write operation is performed in the normal write (long-term guarantee) mode and transitions of Vt distribution states when a write operation is performed in the high-rate write (short-term guarantee) mode.

The write operation in the high-rate write (short-term guarantee) mode and the write operation in the normal write (long-term guarantee) mode are different from each other only in the verify voltages PVS1 (=3.3 V) and PVS2 (=5.8 V) during write operations of data ‘1’ and ‘0’. Regarding other respects of the write operation, the non-volatile semiconductor memory device 1400 of Embodiment 14 is the same as the non-volatile semiconductor memory device 1100 of Embodiment 11, and will not be described in detail.

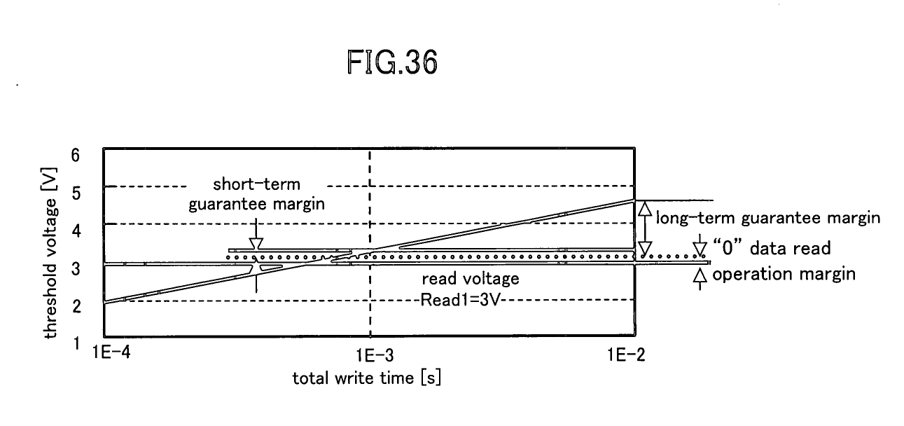

For example, when data ‘1’ and ‘0’ are written from the lowest data ‘1’ distribution in the high-rate write (short-term guarantee) mode in which the verify voltage is lowered, transition of threshold voltages is completed in a total write time (about 1 ms) which is about 1/10 of a time required when a write operation is performed in the normal write (long-term guarantee) mode (about 10 ms), as illustrated in FIG. 36 (a diagram indicating total write time dependency of a memory cell threshold voltage). In other words, the write rate is improved by about one order of magnitude.

Next, the control circuit 12 writes short-term guarantee information (data ‘0’ (‘H’)) into the short-term guarantee flag area 45 so that it is detectable that short-term guarantee data has been written in a sector in which a write operation has been performed in the high-rate write (short-term guarantee) mode.

Next, data corresponding to each sector is read out from the short-term guarantee flag area 45. When at least one piece of data ‘0’ has been detected by the control circuit 12, the control circuit 12 outputs data ‘0’ (‘H’) as a short-term guarantee flag. When all pieces of data in the sector have been detected as data ‘1’, data ‘1’ (‘L’) is output as a short-term guarantee flag. The read and write operations of the short-term guarantee flag area 45 are the same as the read and write operations of the memory cell transistor array 1 in Embodiment 1 and will not be here described.

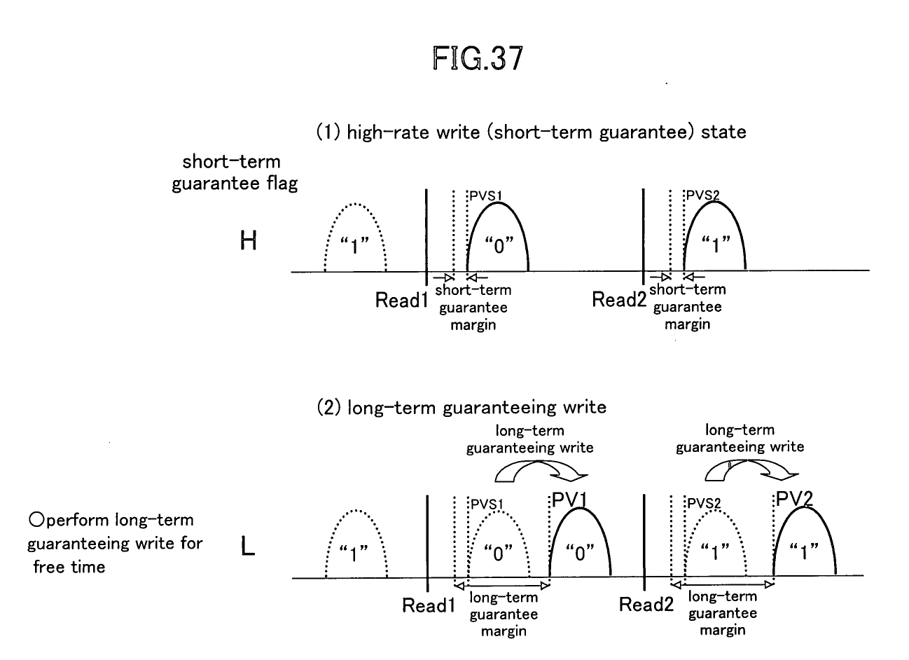

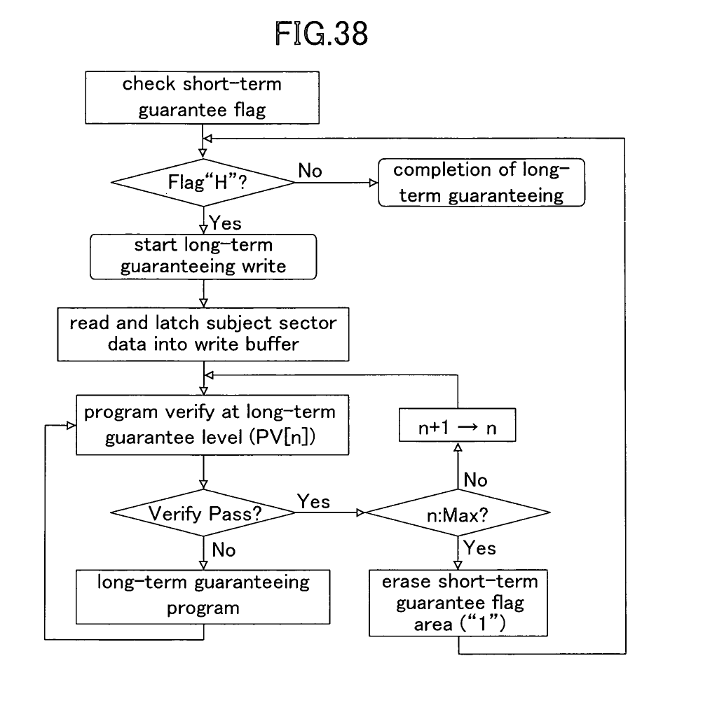

Next, the long-term guaranteeing operation will be described with reference to FIGS. 37 and 38. FIG. 38 is a diagram illustrating a long-term guaranteeing write sequence flow.

The microcomputer (not shown) checks the short-term guarantee flag. When the short-term guarantee flag indicates data ‘1’ (‘L’), all memory array sectors have been written in the normal write (long-term guarantee) mode. Therefore, the long-term guaranteeing operation is not executed. When the short-term guarantee flag indicates data ‘0’ (‘H’), there is at least one sector in which long-term guarantee is required, and a long-term guaranteeing write operation is executed with respect to the sector.

Next, all pieces of data ‘1’ and ‘0’ are read out from a sector to be long-term guaranteed, the read data is transferred to the input data switching circuit 20 by the output data switching circuit 5. The input data switching circuit 20 causes, via the verify circuit 7, the write data latch 8 to latch the transferred data.

Next, the write/erase circuit 44 writes the latch data into a sector in which long-term guaranteeing is being performed, in the normal write (long-term guarantee) mode in which the write verify levels are set to be PV1 and PV2 (a long-term guaranteeing write operation in (2) of FIG. 37). The write operation of the sector in which long-term guaranteeing is being performed is the same as that of Embodiment 11 and will not be here described in detail.

After the series of long-term guaranteeing write operations are performed, the short-term guarantee flag area 45 corresponding to a sector to be subjected to the long-term guaranteeing write operation is erased in a manner similar to the sector erase operation of the memory cell transistor array 1, so that a predetermined bit(s) is reset to be data ‘1’.

Next, as indicated in the long-term guaranteeing write operation sequence flow of FIG. 38, the microcomputer (not shown) checks the short-term guarantee flag again, and a long-term guaranteeing write operation is repeatedly performed until the short-term guarantee flag becomes data ‘1’ (‘L’).

As described above, according to this embodiment, the short-term guarantee flag area 45 and the short-term guarantee flag are provided, and also, the high-rate write (short-term guarantee) mode in which the verify voltage is lowered is provided, thereby making it possible to reduce the threshold voltage shift amount (write time) of data ‘1’ and ‘0’ during a write operation, and the number of times of a verify operation (verify time). In other words, data ‘1’ and ‘0’ can be rewritten at a higher rate.

Also, the microcomputer (not shown) can control the sector long-term guaranteeing operation, so that a long-term guaranteeing write operation can be performed in a free time after a write operation is performed in the high-rate write (short-term guarantee) mode. Therefore, both an apparent high-rate write operation and long-term guarantee can be achieved.

Also, when the short-term guarantee flag indicates data ‘0’ (‘H’), and the maximum Vt distribution level reaches a predetermined level, so that the transition completion flag indicates data ‘0’ (‘H’), an initialization operation is performed with priority, and in accordance with the initialization sequence flow of FIG. 31, the spare sector 41 is used to collect and initialize at least one pair of data ‘0’ and data ‘1’ as long-term guarantee data in the lowest distribution without impairing address matching. Thereby, the long-term guaranteeing write operation can be removed, thereby making it possible to reduce current consumption.

Although all data write operations are performed in the high-rate write (short-term guarantee) mode in this embodiment, a first data write operation may be performed in the normal write (long-term guarantee) mode, and a second and later data write operations may be performed in the high-rate write (short-term guarantee) mode.

### Embodiment 15 of the Invention

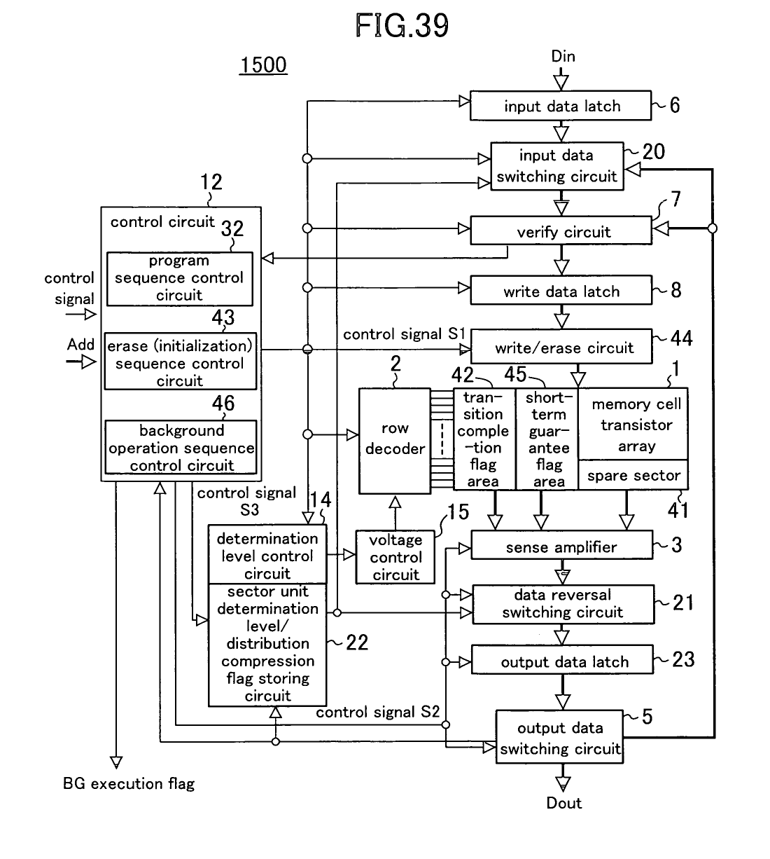

FIG. 39 is a block diagram illustrating a configuration of a non-volatile semiconductor memory device 1500 according to Embodiment 15 of the present invention. As illustrated in FIG. 39, the non-volatile semiconductor memory device 1500 has the same configuration as that of the non-volatile semiconductor memory device 1400, in that a background operation sequence control circuit 46 is provided instead of the power-ON sequence control circuit 36.

The background operation sequence control circuit 46 controls a sector initialization operation so that a sector is initialized in the background during a command waiting time.

The non-volatile semiconductor memory device 1500 also comprises an area (not shown) for storing information indicating that a long-term guaranteeing write operation of a sector is being executed in the background (BG), as a BG execution flag, so that a microcomputer (not shown) can detect that the long-term guaranteeing write operation of the sector is being executed in the background (BG). During the long-term guaranteeing write operation of the sector, the non-volatile semiconductor memory device is in the busy state, so that the BG execution flag is set to be data ‘0’ (‘H’) by the background operation sequence control circuit 46. Also, the BG execution flag is reset to be data ‘1’ (‘L’) by the background operation sequence control circuit 46 after the end of the long-term guaranteeing write operation of the sector.

Hereinafter, an operation of the non-volatile semiconductor memory device 1500 will be described.

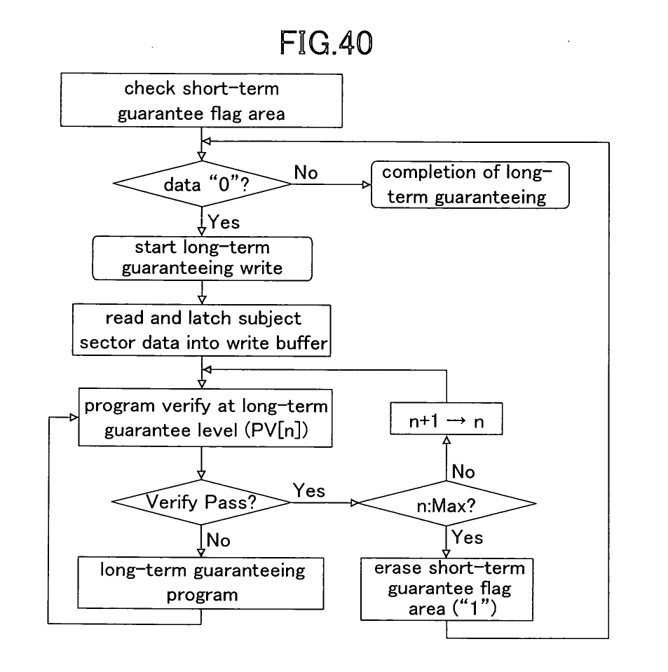

When a control signal is not input from the microcomputer (not shown) to the control circuit 12, the background operation sequence control circuit 46 reads out information from the short-term guarantee flag area 45 via the output data switching circuit 5. When data ‘0’ (‘H’) is written in the short-term guarantee flag area 45, there is at least one short-term guarantee sector. When there is a short-term guarantee sector, the background operation sequence control circuit 46 outputs data ‘0’ (‘H’) as a BG execution flag. Also, the background operation sequence control circuit 46 performs a control so that a long-term guaranteeing write operation of the short-term guarantee sector is performed in accordance with a long-term guaranteeing write operation sequence flow of FIG. 40 in the background (BG). In this case, the background operation sequence control circuit 46 notifies the microcomputer (not shown) that a control signal cannot be received, using the BG execution flag.

After the sector long-term guaranteeing operation in the background (BG) is finished, the background operation sequence control circuit 46 outputs data ‘1’ (‘L’) as a BG execution flag to a microcomputer (not shown) so as to notify the microcomputer that the non-volatile semiconductor memory device 1500 is ready to receive the control signal.

As described above, according to this embodiment, an effect similar to that of the non-volatile semiconductor memory device 1400 of Embodiment 14 is obtained, and by providing the background operation sequence control circuit 46 and the BG execution flag, a long-term guaranteeing write operation can be performed during a free time in which a control signal is not input from the microcomputer (not shown). Therefore, an apparent long-term guaranteeing write operation is eliminated, so that a time required to write data ‘1’ and ‘0’ is reduced, resulting in an improvement in the user convenience.

Also, data ‘0’ (‘H’) is written into the short-term guarantee flag area, and the maximum Vt distribution level reaches a predetermined level, so that there is a sector in which data ‘0’ is written in the transition completion flag area, an initialization operation is performed with priority, and in accordance with the initialization sequence flow of FIG. 33, the spare sector 41 is used to collect and initialize at least one pair of data ‘0’ and data ‘1’ as long-term guarantee data in the lowest distribution without impairing address matching. Thereby, the long-term guaranteeing write operation in the background can be removed, thereby making it possible to reduce current consumption.

### Embodiment 16 of the Invention

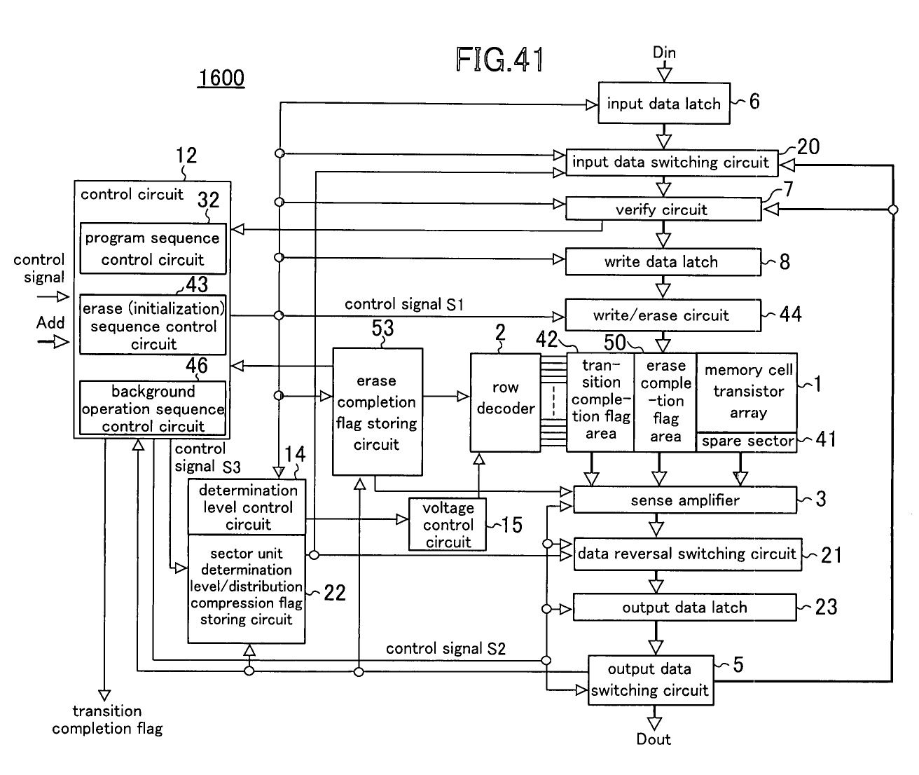

FIG. 41 is a block diagram illustrating a configuration of a non-volatile semiconductor memory device 1600 according to Embodiment 16 of the present invention. As illustrated in FIG. 41, the non-volatile semiconductor memory device 1600 has the same configuration as that of the non-volatile semiconductor memory device 1200, except that an erase completion flag area 50 and an erase completion flag storing circuit 53 are added.

The erase completion flag area 50 is a non-volatile memory area similar to that of the memory cell transistor array 1. The erase completion flag area 50 stores information indicating, for each sector, whether or not the sector is in an erase completed state (erase completion flag information), as an erase completion flag.

The erase completion flag storing circuit 53 has a register area for storing the erase completion flag information written in the erase completion flag area 50, and based on a write address and the erase completion flag information, outputs a write prohibition signal to the control circuit 12.

Hereinafter, an operation of the non-volatile semiconductor memory device 1500 will be described.

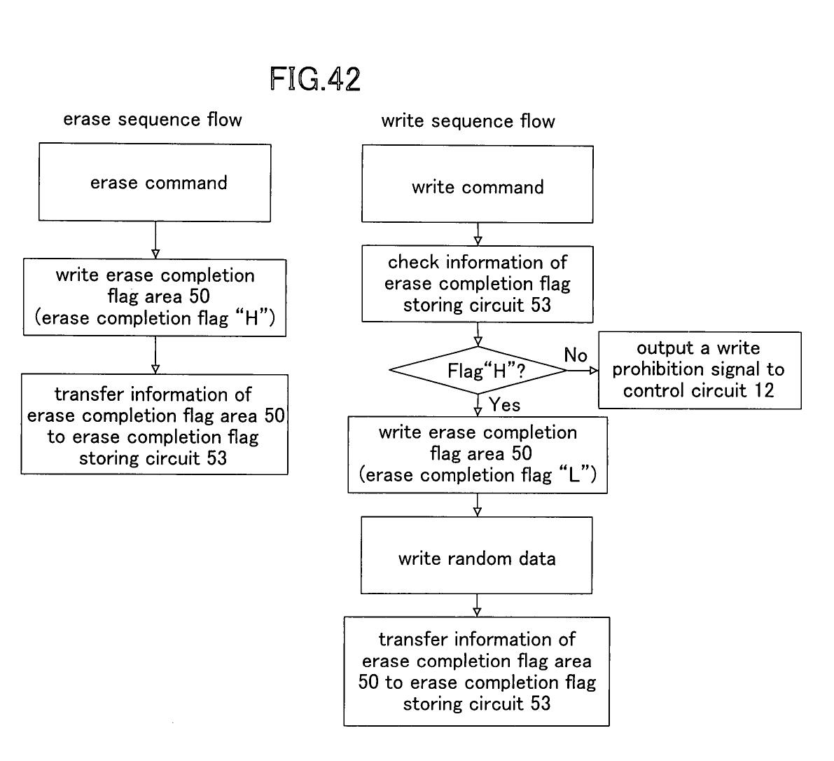

Firstly, an erase operation using an erase command will be described using an erase sequence flow of FIG. 42.

Initially, the microcomputer issues an erase command with respect to a sector to be erased (in this case, generally, random data of ‘0’ and ‘1’ are written in the sector to be erased).

Next, the initialization sequence control circuit 43 writes information indicating that the sector to be erased is in an erased state, into the erase completion flag area 50, so that the erase completion flag is set to be data ‘0’ (‘H’). Thereafter, the information (the erase completion flag indicates data ‘0’ (‘H’)) of the erase completion flag area 50 is transferred to the erase completion flag storing circuit 53. Thus, the erase operation is completed. In this case, only the information of the erase completion flag is changed without changing the random data of ‘0’ and ‘1’ written in the sector to be erased.

Next, a write operation will be described using a write sequence flow of FIG. 42.

Initially, a microcomputer issues a write command with respect to a sector to be written.

Next, information of the erase completion flag storing circuit 53 is checked by the initialization sequence control circuit 43. When the erase completion flag of the sector to be written indicates data ‘1’ (‘L’), the user data has been written, and therefore, a write prohibition signal is output to the control circuit 12. When the erase completion flag of the sector to be written indicates data ‘0’ (‘H’), a write operation is permitted, and therefore, the information in the erase completion flag area 50 is erased, and the erase completion flag is set to be data ‘1’ (‘L’). Thereafter, a random data write operation of ‘0’ and ‘1’ is performed with respect to the sector to be written. Thereafter, the information of the erase completion flag area 50 is transferred to the erase completion flag storing circuit 53, and the write operation is completed. In this case, the random data write operation of ‘0’ and ‘1’ is similar to that of Embodiment 12.

As described above, according to this embodiment, by providing the erase completion flag area 50 and the erase completion flag storing circuit 53, an erased state can be achieved by raising the erase flag without shifting a threshold voltage distribution during an erase operation in accordance with an erase command. Therefore, a time required to perform an erase operation itself can be reduced as compared to conventional erase operations, thereby making it possible to significantly reduce an erase time.

### Embodiment 17 of the Invention

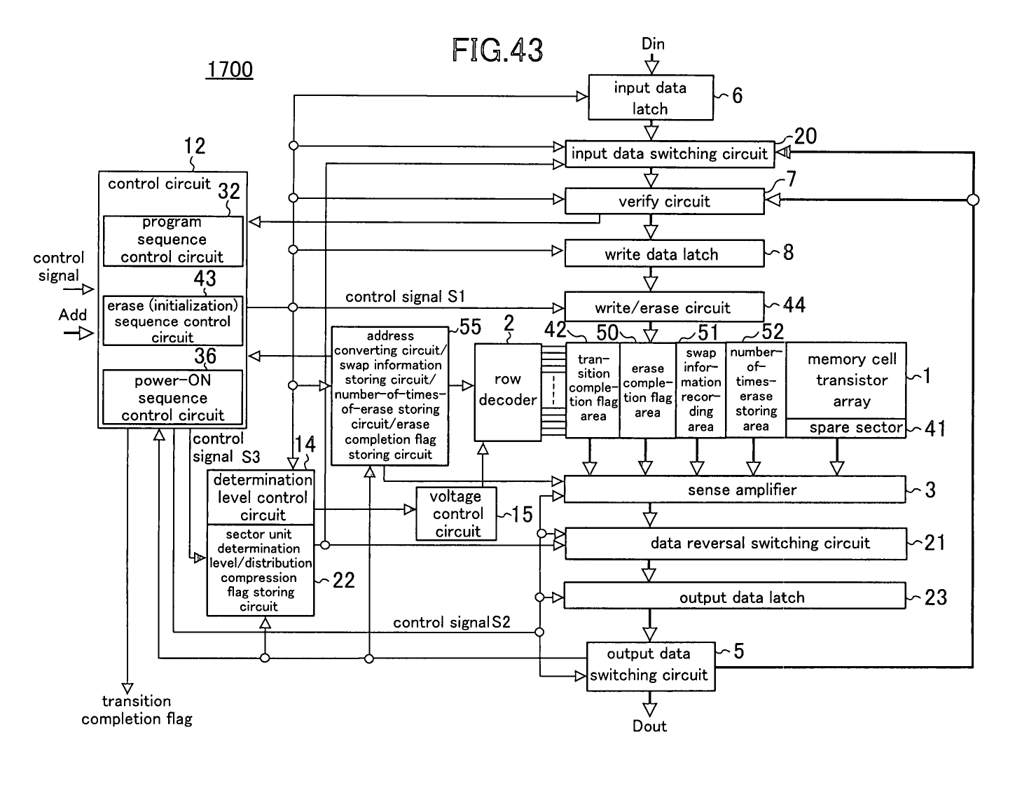

FIG. 43 is a block diagram illustrating a configuration of a non-volatile semiconductor memory device 1700 according to Embodiment 17 of the present invention.

As illustrated in FIG. 43, the non-volatile semiconductor memory device 1700 has the same configuration as that of the non-volatile semiconductor memory device 1600 of Embodiment 16, except that a swap information memory area 51, an number-of-times-of-erase area 52, and an address converting circuit/swap information storing circuit/number-of-times-of-erase storing circuit/erase completion flag storing circuit 55 are provided so that, during initialization, the number of times of an erase operation of a free sector is searched for, a sector requiring initialization is swapped with a sector having a smallest number of times of an erase operation, and distributions corresponding to ‘0’ and ‘1’ are transferred and initialized with respect to the free sector having the smallest number of times of an erase operation.

The swap information memory area 51 is a non-volatile memory area in which, when the number of times of an erase operation of a free sector is checked during an initialization operation, and a sector requiring initialization is swapped with a free sector having a smallest number of times of an erase operation, sector information (swap sector information) indicating whether or not swapping has been performed is recorded for each sector.

The number-of-times-of-erase memory area 52 is a non-volatile memory area in which the number of times of shift to a lowest distribution corresponding to data ‘1’ can be stored for each sector.

The address converting circuit/swap information storing circuit/number-of-times-of-erase storing circuit/erase completion flag storing circuit 55 has a register area for storing information about an erase completion flag written in the erase completion flag area 50, a register area for storing information about a swap sector written in the swap information memory area 51, and a register area for storing information about the number of times of an erase operation written in the number-of-times-of-erase memory area 52, and has a function of performing sector address conversion based on the swap sector information, the information about the number of times of an erase operation, the information about an erase completion flag, and the like for each sector, and a function of outputting a write prohibition signal to the control circuit 12 based on information about a write address and an erase completion flag.

Hereinafter, an operation of the non-volatile semiconductor memory device 1700 will be described.

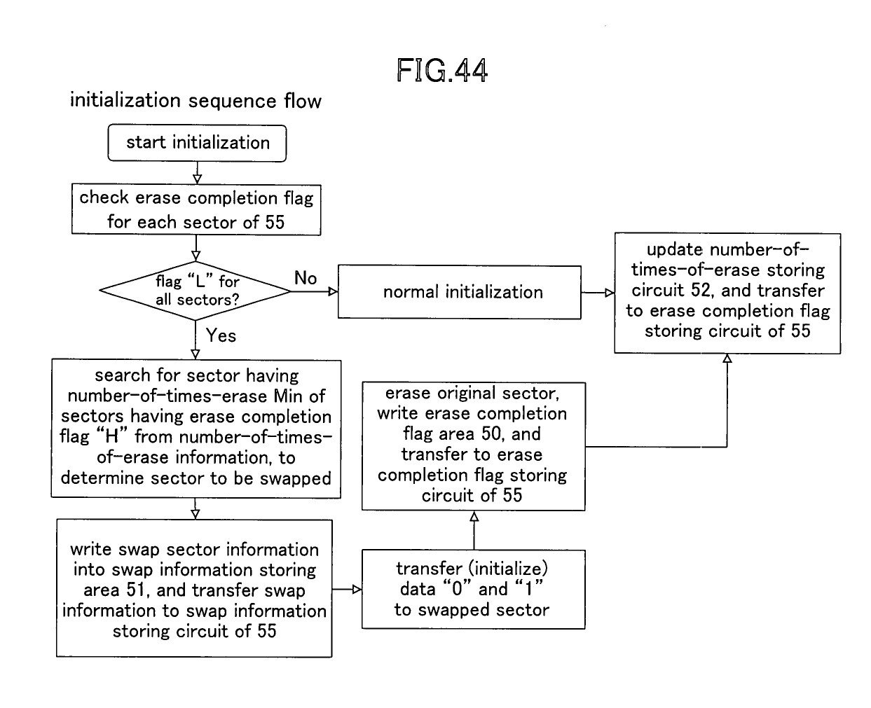

Firstly, initialization will be described using an initialization sequence flow of FIG. 44. A flow until the start of initialization is similar to that of Embodiment 12 of the present invention. After the start of initialization, an erase completion flag is checked for each sector of the address converting circuit/swap information storing circuit/number-of-times-of-erase storing circuit/erase completion flag storing circuit 55. When there is not a free sector for all sectors (the erase completion flags of all the sectors indicate data ‘1’ (‘L’)), initialization is performed with respect to a sector to be erased itself. When there is a free sector (there is a sector having an erase completion flag indicating data ‘0’ (‘H’)), a sector which has an erase completion flag indicating data ‘0’ (‘H’) and a smallest number of times of an erase operation is selected as a sector to be swapped, based on the information about the number of times of an erase operation and the information about an erase completion flag of the address converting circuit/swap information storing circuit/number-of-times-of-erase storing circuit/erase completion flag storing circuit 55.

Thereafter, information about the swap sector is written into the swap information memory area 51. The swap sector information of the swap information memory area 51 is transferred to as a register of the swap information storing circuit of the address converting circuit/swap information storing circuit/number-of-times-of-erase storing circuit/erase completion flag storing circuit 55. Thereafter, based on the information of the register of the swap information storing circuit of the address converting circuit/swap information storing circuit/number-of-times-of-erase storing circuit/erase completion flag storing circuit 55, sector address conversion is performed to swap a sector to be erased. Data ‘0’ and ‘1’ are transferred (initialized) into the swapped sector. Thereby, an erase operation is performed with respect to a sector which was originally to be initialized (swapped sector). A write operation is performed with respect to the erase completion flag area of the swap information memory area 51 so that the erase completion flag is set to be data ‘0’ (‘H’), and the information is transferred to a register of the erase completion flag storing circuit of the address converting circuit/swap information storing circuit/number-of-times-of-erase storing circuit/erase completion flag storing circuit 55.

Thereafter, either when a normal initialization operation is performed or when an initialization operation is performed after swapping, the number-of-times-of-erase memory area 52 is updated so that the number of times of an erase operation is incremented, and information about the number of times of an erase operation is transferred to a register of the number-of-times-of-erase storing circuit of the address converting circuit/swap information storing circuit/number-of-times-of-erase storing circuit/erase completion flag storing circuit 55. Thus, the initialization is completed. The subsequent flow is similar to that of Embodiment 12 of the present invention.

As described above, according to the non-volatile semiconductor memory device 1700, as compared to the configuration of the non-volatile semiconductor memory device 1600 of Embodiment 16, the swap information memory area 51, the number-of-times-of-erase memory area 52, and the address converting circuit/swap information storing circuit/number-of-times-of-erase storing circuit/erase completion flag storing circuit 55 are provided, and during an initialization operation, the number of times of an erase operation of a free sector is searched for, and a sector requiring initialization is swapped with a free sector having a smallest number of times of an erase operation. Distributions corresponding to data ‘0’ and ‘1’ are transferred to the free sector having the smallest number of times of an erase operation, thereby making it possible to achieve initialization. Therefore, the number of times of an erase operation can be leveled with respect to all sectors, thereby making it possible to achieve a highly reliable non-volatile semiconductor memory device.

### Embodiment 18 of the Invention

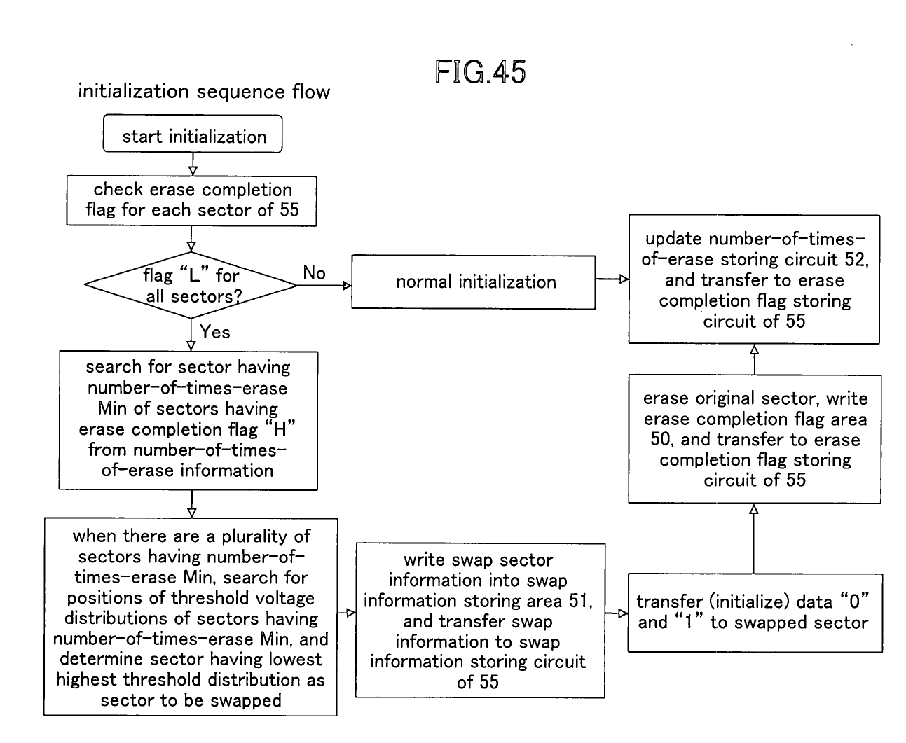

When there are a plurality of free sectors having a smallest number of times of an erase operation, the non-volatile semiconductor memory device 1700 of Embodiment 17 may be controlled as indicated by a flowchart of FIG. 45.

Embodiment 18 is characterized in that, in the non-volatile semiconductor memory device 1700 of Embodiment 17 of the present invention, when there are a plurality of free sectors having a smallest number of times of an erase operation, a position of a highest threshold voltage distribution is searched for, and a sector having a lowest highest threshold voltage distribution is swapped with a sector requiring initialization. Hereinafter, the operation will be described.

Firstly, initialization will be described using an initialization sequence flow of FIG. 45. A flow until the start of initialization is similar to that of Embodiment 12 of the present invention. After the start of initialization, an erase completion flag for each sector of the address converting circuit/swap information storing circuit/number-of-times-of-erase storing circuit/erase completion flag storing circuit 55 is checked. When there is not a free sector for all sectors (the erase completion flags of all the sectors indicate data ‘1’ (‘L’)), initialization is performed with respect to a sector to be erased itself. When there is a free sector (there is a sector having an erase completion flag indicating data ‘0’ (‘H’)), a sector which has an erase completion flag indicating data ‘0’ and a smallest number of times of an erase operation is searched for, based on the information about the number of times of an erase operation and the information about an erase completion flag of the address converting circuit/swap information storing circuit/number-of-times-of-erase storing circuit/erase completion flag storing circuit 55.

Thereafter, when there are a plurality of sectors having an erase completion flag indicating data ‘0’ (‘H’) and a smallest number of times of an erase operation, a position of a threshold voltage distribution of a sector having a smallest number of times of an erase operation is searched for, and a sector having a lowest highest distribution is selected as a sector to be swapped. Thereafter, information about the swap sector is written into the swap information memory area 51. The swap sector information of the swap information memory area 51 is transferred to the register of the swap information storing circuit of the address converting circuit/swap information storing circuit/number-of-times-of-erase storing circuit/erase completion flag storing circuit 55.

Thereafter, based on the information of the register of the swap information storing circuit of the address converting circuit/swap information storing circuit/number-of-times-of-erase storing circuit/erase completion flag storing circuit 55, sector address conversion is performed to swap a sector to be erased. Data ‘0’ and ‘1’ are transferred (initialized) into the swapped sector. Thereby, an erase operation is performed with respect to a sector which was originally to be initialized (swapped sector). A write operation is performed with respect to the erase completion flag area 50 so that the erase completion flag is set to be data ‘0’ (‘H’), and the information is transferred to the register of the erase completion flag storing circuit of the address converting circuit/swap information storing circuit/number-of-times-of-erase storing circuit/erase completion flag storing circuit 55.

Thereafter, either when a normal initialization operation is performed or when an initialization operation is performed after swapping, the number-of-times-of-erase memory area 52 is updated, the number of times of an erase operation is incremented, and information about the number of times of an erase operation is transferred to the register of the number-of-times-of-erase storing circuit of the address converting circuit/swap information storing circuit/number-of-times-of-erase storing circuit/erase completion flag storing circuit 55. Thus, the initialization is completed. The subsequent flow is similar to that of Embodiment 12 of the present invention.

As described above, according to Embodiment 18, in the non-volatile semiconductor memory device 1700 of Embodiment 17, when there is a plurality of free sectors having a smallest number of times of an erase operation, a position of an highest threshold voltage distribution is searched for, and a sector having a lowest highest threshold voltage distribution is swapped with a sector requiring initialization. Thereby, the number of times of a rewrite operation until the highest threshold voltage distribution reaches the maximum level can be increased. Therefore, as compared to Embodiment 17, the user convenience can be further improved.

### Embodiment 19 of the Invention

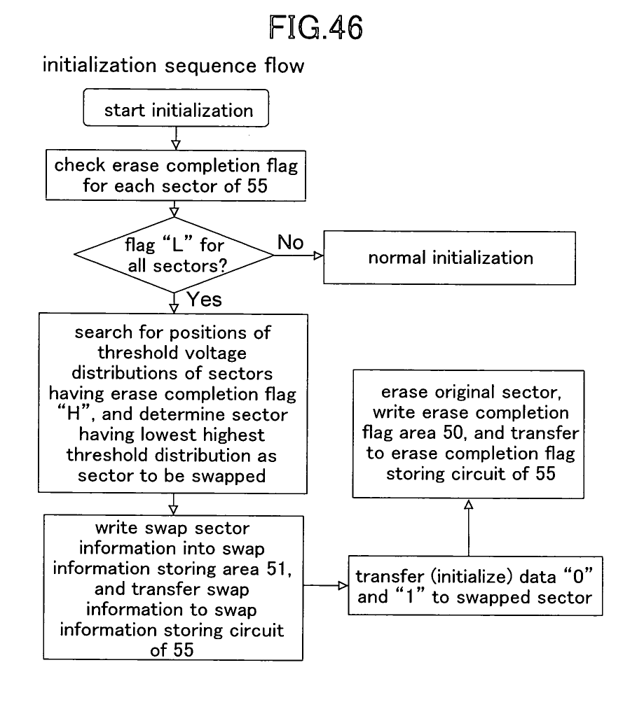

Alternatively, the non-volatile semiconductor memory device 1700 of Embodiment 17 may be controlled as indicated by a flowchart of FIG. 46. Note that, in this embodiment, the number-of-times-of-erase memory area 52 is either provided or not provided.

Embodiment 19 is characterized in that, in the non-volatile semiconductor memory device 1700 of Embodiment 17 of the present invention, the swap information memory area 51 and the address converting circuit/swap information storing circuit/number-of-times-of-erase storing circuit/erase completion flag storing circuit 55 are configured so that, during an initialization operation, a position of a highest threshold voltage distribution can be searched for, a sector requiring initialization can be swapped with a sector having a lowest highest threshold voltage distribution, and data can be transferred to the sector having the lowest highest threshold voltage distribution, thereby achieving initialization. Hereinafter, the operation will be described.

Firstly, initialization will be described using an initialization sequence flow of FIG. 46. A flow until the start of initialization is similar to that of Embodiment 12 of the present invention. After the start of initialization, an erase completion flag for each sector of the address converting circuit/swap information storing circuit/number-of-times-of-erase storing circuit/erase completion flag storing circuit 55 is checked. When there is not a free sector for all sectors (the erase completion flags of all the sectors indicate data ‘1’ (‘L’)), initialization is performed with respect to a sector to be erased itself. When there is a free sector (there is a sector having an erase completion flag indicating data ‘0’ (‘H’)), a sector which has an erase completion flag indicating data ‘0’ (‘H’) and a lowest highest threshold voltage distribution is obtained by searching the information about an erase completion flag and the threshold voltage distribution of the address converting circuit/swap information storing circuit/number-of-times-of-erase storing circuit/erase completion flag storing circuit 55, and the sector which has the lowest highest threshold voltage distribution is selected as a sector to be swapped. Thereafter, information about the swap sector is written into the swap information memory area 51. The swap sector information of the swap information memory area 51 is transferred to the register of the swap information storing circuit of the address converting circuit/swap information storing circuit/number-of-times-of-erase storing circuit/erase completion flag storing circuit 55.

Thereafter, based on the information of the register of the swap information storing circuit of the address converting circuit/swap information storing circuit/number-of-times-of-erase storing circuit/erase completion flag storing circuit 55, sector address conversion is performed to swap a sector to be erased. Data ‘0’ and ‘1’ are transferred (initialized) into the swapped sector. Thereby, an erase operation is performed with respect to a sector which was originally to be initialized (swapped sector). A write operation is performed with respect to the erase completion flag area 50 so that the erase completion flag is set to be data ‘0’ (‘H’), and the information is transferred to the register of the erase completion flag storing circuit of the address converting circuit/swap information storing circuit/number-of-times-of-erase storing circuit/erase completion flag storing circuit 55. Thus, the initialization is completed. The subsequent flow is similar to that of Embodiment 17 of the present invention.

As described above, according to Embodiment 19, during initialization, a position of a highest threshold voltage distribution is searched for, a sector requiring initialization is swapped with a lowest highest threshold voltage distribution sector, and data is transferred to the lowest highest threshold voltage distribution sector, thereby achieving initialization. Therefore, the number of times of a rewrite operation until the highest threshold voltage distribution reaches the maximum level can be increased, thereby making it possible to improve the user convenience.

### Embodiment 20 of the Invention

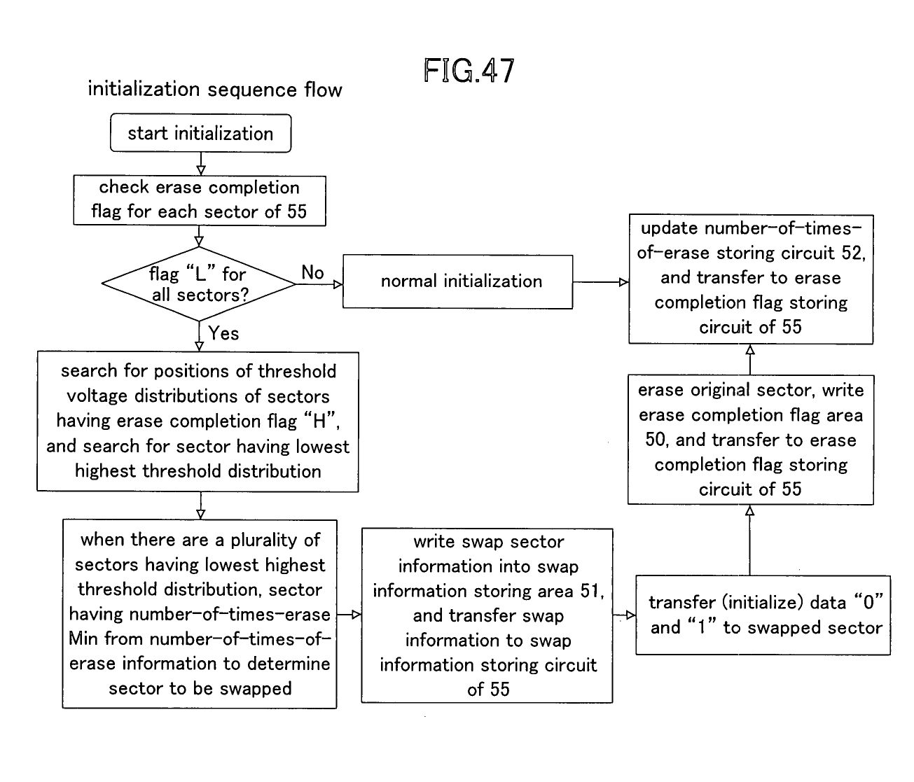

Alternatively, the non-volatile semiconductor memory device 1700 of Embodiment 17 may be controlled as indicated by a flowchart of FIG. 47.

Embodiment 20 is characterized in that, in the non-volatile semiconductor memory device of Embodiment 19 of the present invention, when there are a plurality of sectors having a lowest highest threshold voltage distribution, the number of times of an erase operation is searched for, and a sector having a smallest number of times of an erase operation is swapped with a sector requiring initialization. Hereinafter, the operation will be described.

Firstly, initialization will be described using an initialization sequence flow of FIG. 47. A flow until the start of initialization is similar to that of Embodiment 17 of the present invention. After the start of initialization, an erase completion flag for each sector of the address converting circuit/swap information storing circuit/number-of-times-of-erase storing circuit/erase completion flag storing circuit 55 is checked. When there is not a free sector for all sectors (the erase completion flags of all the sectors indicate data ‘1’ (‘L’)), initialization is performed with respect to a sector to be erased itself. When there is a free sector (there is a sector having an erase completion flag indicating data ‘0’ (‘H’)), a sector which has an erase completion flag indicating data ‘0’ (‘H’) and a lowest highest threshold voltage distribution is obtained by searching the information about an erase completion flag and the threshold voltage distribution of the address converting circuit/swap information storing circuit/number-of-times-of-erase storing circuit/erase completion flag storing circuit 55. When there are a plurality of sectors having the lowest highest threshold voltage distribution, a sector having a smallest number of times of an erase operation is selected as a sector to be swapped, based on the information about the number of times of an erase operation of the threshold voltage distribution of the address converting circuit/swap information storing circuit/number-of-times-of-erase storing circuit/erase completion flag storing circuit 55.

Thereafter, information about the swap sector is written into the swap information memory area 51. The swap sector information of the swap information memory area 51 is transferred to the register of the swap information storing circuit of the address converting circuit/swap information storing circuit/number-of-times-of-erase storing circuit/erase completion flag storing circuit 55. Thereafter, based on the information of the register of the swap information storing circuit of the address converting circuit/swap information storing circuit/number-of-times-of-erase storing circuit/erase completion flag storing circuit 55, sector address conversion is performed to swap a sector to be erased. Data ‘0’ and ‘1’ are transferred (initialized) into the swapped sector. Thereby, an erase operation is performed with respect to a sector which was originally to be initialized (swapped sector). A write operation is performed with respect to the erase completion flag area 50 so that the erase completion flag is set to be data ‘0’ (‘H’), and the information is transferred to the register of the erase completion flag storing circuit of the address converting circuit/swap information storing circuit/number-of-times-of-erase storing circuit/erase completion flag storing circuit 55. Thereafter, either when a normal initialization operation is performed or when an initialization operation is performed after swapping, the number-of-times-of-erase memory area 52 is updated, the number of times of an erase operation is incremented, and information about the number of times of an erase operation is transferred to the register of the number-of-times-of-erase storing circuit of the address converting circuit/swap information storing circuit/number-of-times-of-erase storing circuit/erase completion flag storing circuit 55. Thus, the initialization is completed. The subsequent flow is similar to that of Embodiment 17 of the present invention.

As described above, according to Embodiment 20, in the non-volatile semiconductor memory device of Embodiment 19 of the present invention, when there are a plurality of sectors having a lowest highest threshold voltage distribution, the number of times of an erase operation is searched for, and a sector having a smallest number of times of an erase operation is swapped with a sector requiring initialization. Thereby, as compared to the non-volatile semiconductor memory device of Embodiment 19 of the present invention, the number of times of an erase operation can be leveled with respect to all sectors, thereby making it possible to achieve a highly reliably non-volatile semiconductor memory device.

### Embodiment 21 of the Invention

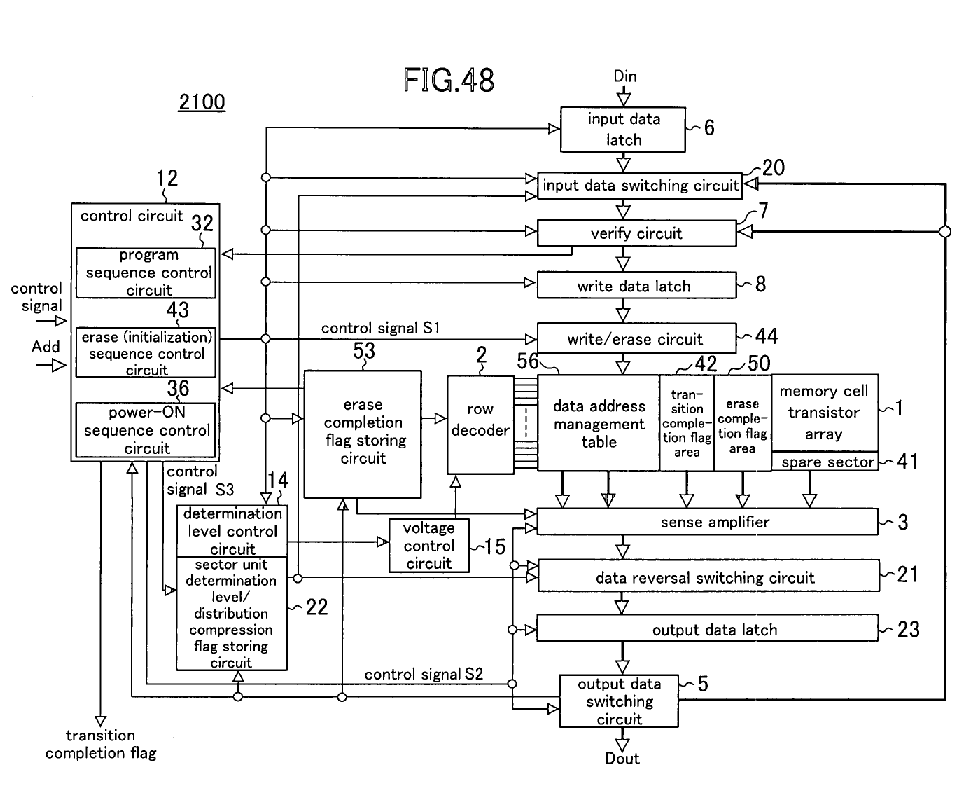

FIG. 48 is a block diagram illustrating a configuration of a non-volatile semiconductor memory device 2100 according to Embodiment 21 of the present invention.

As illustrated in FIG. 48, Embodiment 21 is characterized in that, in the non-volatile semiconductor memory device 1600 of Embodiment 16 of the present invention, a data address management table 56 is provided, and data in an area indicated by the data address management table 56 can be fixed. Specifically, the data address management table 56 is composed of a non-volatile memory area.

The non-volatile semiconductor memory device 2100, when writing a small number of bits into an erase-completed sector in which data ‘0’ and ‘1’ coexist according to an erase completion flag, does not need to perform a write operation with respect to data within a predetermined address range (a range within which write data corresponding to the range is ‘1’), and therefore, has a function of causing data within the address range written in the data address management table to be invariably data ‘1’ during a read operation so as to achieve an efficient write operation. Hereinafter, an operation of the non-volatile semiconductor memory device 2100 will be described.

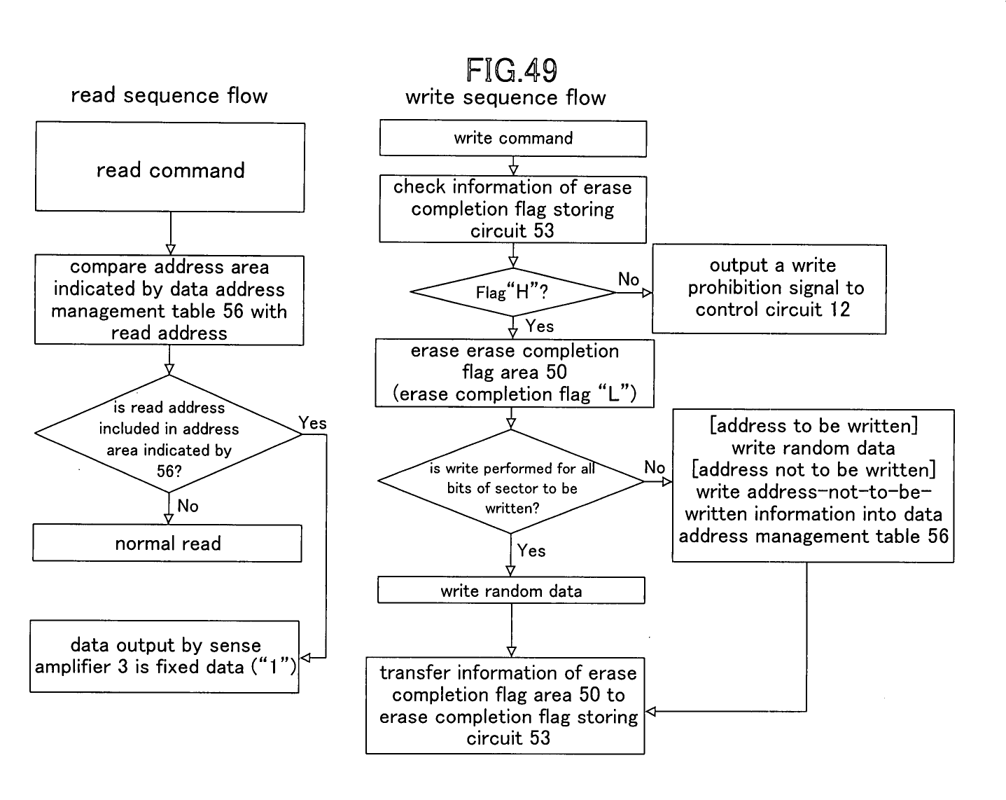

A write operation will be described using a write sequence flow of FIG. 49. Initially, a microcomputer (not shown) issues a write command with respect to a sector to be written. Next, the initialization sequence control circuit 43 checks information of the erase completion flag storing circuit 53. When the erase completion flag of the sector to be written indicates data ‘1’, the user data has been written, and the erase completion flag storing circuit 53 outputs a write prohibition signal to the control circuit 12. When the erase completion flag of the sector to be written indicates data ‘0’ (‘H’), a write operation can be performed, the information of the erase completion flag area 50 is erased, and the erase completion flag is set to be data ‘1’ (‘L’).

Thereafter, it is checked whether all bits in the sector to be written are subjects of the write operation. When all the bits in the sector to be written are subjects of the write operation, a random data write operation is performed. When otherwise, a random data write operation is performed with respect to a bit(s) of an address to be written, and address-not-to-be-written information is written into the data address management table 56 with respect to a bit(s) which is not to be written. In this case, for example, only information about a start address and an end address of an address which is not to be written is written. In either case, the information of the erase completion flag area 50 is transferred to the erase completion flag storing circuit 53, and the write operation is ended. In this case, a random data write operation of data ‘0’ and ‘1’ is similar to that of Embodiment 12.

Next, a read operation will be described using a read sequence flow of FIG. 49. Initially, the microcomputer issues a read command, so that a read operation is started. Next, the microcomputer reads out the data address management table 56, and when an address to be read is not within an address range read from the data address management table 56, performs a normal read operation. When the address to be read is within the address range read out from the data address management table 56, fixed data (in this example, data ‘1’) is output as read data from the sense amplifier 3. The normal read operation is similar to that of Embodiment 12 of the present invention.

As described above, according to Embodiment 21, in the configuration of the non-volatile semiconductor memory device of Embodiment 16 of the present invention, the data address management table 56 is provided, so that read data can be fixed with respect to data in an area indicated on the data address management table 56. Thereby, when a small number of bits are written into an erase-completed sector in which data ‘0’ and ‘1’ coexist, the shift of a threshold voltage distribution with respect to a bit(s) other than an address to be written can be eliminated, thereby making it possible to achieve a non-volatile semiconductor memory device having a short write time.

As described above, the non-volatile semiconductor memory device of the present invention has an effect that, during a data rewrite operation, a data erase operation performed in conventional non-volatile semiconductor memory devices is no longer required, so that a rewrite time can be significantly reduced. The non-volatile semiconductor memory device of the present invention is useful as a non-volatile semiconductor memory device which has a memory cell for storing data using a plurality of threshold voltage distribution states, and the like.

What is claimed is:

1. A non-volatile semiconductor memory device for performing data write and read operations in accordance with an input command, comprising:
a memory cell array including a plurality of memory cells having three or more threshold voltage distributions in a single electric charge accumulation portion; and
a program sequence control circuit for causing the memory cell to store each piece of data included in a data set composed of a plurality of data values, in association with any of the three or more threshold voltage distributions, and shifting a threshold voltage distribution used for data storage in one direction when a rewrite operation is performed with respect to the data stored in the memory cell, thereby performing a data rewrite operation.

2. The non-volatile semiconductor memory device of claim 1, wherein the program sequence control circuit causes the memory cell to store data in a manner which invariably associates the same data in the data set with a lowest or highest threshold voltage distribution of the three or more threshold voltage distributions.

3. The non-volatile semiconductor memory device of claim 2, wherein the program sequence control circuit causes the memory cell to store data using two consecutive threshold voltage distributions of the three or more threshold voltage distributions.

4. The non-volatile semiconductor memory device of claim 3, wherein, when a rewrite operation is performed with respect to data stored using an (n−1)-th distribution (n: a natural number) and a n-th distribution, the program sequence control circuit creates a state in which only the n-th distribution is used, before shifting a used threshold voltage distribution to an (n+1)-th distribution, depending on given data.

5. The non-volatile semiconductor memory device of claim 3, wherein, when a rewrite operation is performed with respect to data stored using an (n−1)-th distribution (n: a natural number) and a n-th distribution, the program sequence control circuit directly shifts used threshold voltage distributions to the n-th distribution and an (n+1)-th distribution, depending on given data.

6. The non-volatile semiconductor memory device of claim 2, wherein the data set is composed of binary data, and
the program sequence control circuit causes the memory cell to store the binary data using the three or more threshold voltage distributions.

7. The non-volatile semiconductor memory device of claim 6, wherein the program sequence control circuit fixedly associates one piece of data of the data set with the highest or lowest threshold voltage distribution, and when a rewrite operation is performed with respect to stored data, shifts a threshold voltage distribution in only a memory cell or memory cells which require transition to the highest or lowest threshold voltage distribution.

8. The non-volatile semiconductor memory device of claim 1, wherein the program sequence control circuit causes the memory cell to store data by associating a plurality of data sets with the three or more threshold voltage distributions.

9. The non-volatile semiconductor memory device of claim 8, wherein the data set is composed of binary data, and
the program sequence control circuit causes the memory cell to store the binary data in association with two consecutive threshold voltage distributions.

10. The non-volatile semiconductor memory device of claim 9, further comprising:
a preliminary write section for changing a memory cell in an n-th distribution state into an (n+1)-th distribution state; and
a data write section for shifting only a memory cell to which data different from data corresponding to an (n+1)-th distribution state is to be written, to an ((n+2)-th distribution.

11. The non-volatile semiconductor memory device of claim 8, wherein the data set is composed of binary data, and
the program sequence control circuit causes the memory cell to store the binary data using the three or more threshold voltage distributions.

12. The non-volatile semiconductor memory device of claim 11, wherein the program sequence control circuit, when rewriting data, shifts a threshold voltage distribution of only a memory cell or memory cells in which data is to be changed, to an upper level.

13. The non-volatile semiconductor memory device of claim 11, further comprising:
a data compression sequence control circuit for compressing the number of used distributions from a state in which three or more threshold voltage distributions are used in the memory cell array to a state in which two threshold voltage distributions which are an m-th threshold voltage distribution (m: a natural number) and an (m+1)-th threshold voltage distribution are used, in the background, when an operation is not executed after a data rewrite operation is finished.

14. The non-volatile semiconductor memory device of claim 13, further comprising:
a distribution compression flag storing circuit for storing compression completion information indicating whether or not compression of the number of distributions performed by the data compression sequence control circuit has been completed; and
a read circuit for selecting any of a multi-level read mode in which a plurality of read determination levels are successively used to read data from the memory cell, and a single-level read mode in which a single read determination level is used to read data, based on the compression completion information stored in the distribution compression flag storing circuit, to read out data from the memory cell.

15. The non-volatile semiconductor memory device of claim 14, further comprising:
a determination level storing circuit for storing determination level information indicating a determination level which is used when data is read out from the memory cell; and
a power-ON sequence control circuit for causing the distribution compression flag storing circuit to store the compression completion information, and causing the determination level storing circuit to store the determination level information, when power is turned ON.

16. The non-volatile semiconductor memory device of claim 14, further comprising:
a determination level storing circuit for storing determination level information indicating a determination level which is used when data is read out from the memory cell;
a non-volatile distribution compression flag area for storing the compression completion information;
a non-volatile determination level memory area for storing the determination level information; and
a power-ON sequence control circuit for writing the compression completion information stored in the distribution compression flag area into the distribution compression flag storing circuit, and writing the determination level information stored in the determination level memory area into the determination level storing circuit, after the data compression sequence control circuit compresses the number of distributions,
wherein the data compression sequence control circuit stores the compression completion information into the distribution compression flag area, and the determination level information into the determination level memory area, after compressing the number of distributions.

17. The non-volatile semiconductor memory device of claim 1, further comprising:
a determination level storing circuit for storing determination level information indicating a determination level which is used when data is read out from the memory cell; and
a power-ON sequence control circuit for selecting a determination level to be used to read data by performing a read operation with respect to each memory cell, and causing the determination level storing circuit to store the determination level as the determination level information.

18. The non-volatile semiconductor memory device of claim 17, further comprising:
a non-volatile used distribution position storing area for storing threshold voltage distribution position information indicating a position of a threshold voltage distribution used in the memory cell,
wherein the power-ON sequence control circuit causes the determination level storing circuit to store determination level information in association with the threshold voltage distribution position information stored in the used distribution position storing area.

19. The non-volatile semiconductor memory device of claim 17, further comprising:
a monitor bit having the same structure as that of the memory cell, for invariably storing the same data,
wherein the power-ON sequence control circuit performs a read operation with respect to the monitor bit to specify the position of the threshold voltage distribution, and causes the determination level storing circuit to store determination level information obtained, depending on the specified position.

20. The non-volatile semiconductor memory device of claim 1, further comprising:
an initialization sequence control circuit for shifting a threshold voltage distribution to be used for data storage in a direction opposite to a shift direction when a data write operation is performed so that data stored in each memory cell corresponds to a threshold voltage distribution successively from a lowest threshold voltage distribution or a highest threshold voltage distribution,
wherein the data set is composed of binary data.

21. The non-volatile semiconductor memory device of claim 20, further comprising:
a transition completion flag indicating completion of shifting in a direction in which the threshold voltage distribution increases, when a threshold voltage distribution having a maximum usable voltage is used.

22. The non-volatile semiconductor memory device of claim 20, wherein the initialization sequence control circuit performs the initialization operation in the background when waiting for an input of the command.

23. The non-volatile semiconductor memory device of claim 1, further comprising:
a write section having a first write function of performing a write operation with respect to each piece of write data to target a first write level when rewriting data stored in the memory cell, and a function of performing a write operation with respect to each piece of write data to target a second write level which is different from the first write level, when rewriting data stored in the memory cell; and
a write level selection section for selecting any one of the first write level and the second write level for each data write operation.

24. The non-volatile semiconductor memory device of claim 23, further comprising:
a determination section for determining data written by the first write function;
a data holding section for holding the data determined by the determination section; and
a long-term guaranteeing write operation section for performing an additional write operation using the data held by the data holding section.

25. The non-volatile semiconductor memory device of claim 23, further comprising:
a write function determining flag indicating, after data is written by the first write function, that the written data is data written by the first write function.

26. The non-volatile semiconductor memory device of claim 24, wherein the long-term guaranteeing write operation section performs the additional write operation in the background when waiting for an input of the command.

27. The non-volatile semiconductor memory device of claim 23, further comprising:
an initialization sequence control circuit for shifting a threshold voltage distribution to be used for data storage in a direction opposite to a shift direction when a data write operation is performed so that data stored in each memory cell corresponds to a threshold voltage distribution successively from a lowest threshold voltage distribution,
wherein the data set is composed of binary data.

28. The non-volatile semiconductor memory device of claim 27, wherein the initialization sequence control circuit performs the initialization in the background when waiting for an input of the command.

29. The non-volatile semiconductor memory device of claim 1, further comprising:
an erase completion flag indicating whether or not data in the memory cell is an erased state,
wherein the program sequence control circuit, when causing the memory cell to be in the erased state, rewrites the erase completion flag so that the erase completion flag indicates that the memory cell is in the erased state, without rewriting the data in the memory cell.

30. The non-volatile semiconductor memory device of claim 29, further comprising:
an initialization sequence control circuit for initializing the memory cell into the erased state in units of a sector,
wherein, during initialization, the initialization sequence control circuit searches for a free sector having a smallest number of times of an erase operation, swaps data in a sector to be initialized with data in the free sector having the smallest number of times of an erase operation, and initializes the free sector having the smallest number of times of an erase operation.

31. The non-volatile semiconductor memory device of claim 30, wherein, during initialization, when there is a plurality of free sectors having the smallest number of times of an erase operation, the initialization sequence control circuit searches for a position of a highest threshold voltage distribution, and swaps data in a sector having a lowest highest threshold voltage distribution with data in the sector requiring initialization.

32. The non-volatile semiconductor memory device of claim 29, wherein the initialization sequence control circuit searches for a position of a highest threshold voltage distribution, swaps data in the sector requiring initialization with data in a sector having a lowest highest threshold voltage distribution, and initializes the sector having the lowest highest threshold voltage distribution.

33. The non-volatile semiconductor memory device of claim 32, wherein, during initialization, when there are a plurality of lowest highest threshold voltage distributions, the initialization sequence control circuit searches the number of times of an erase operation, and swaps data in a sector having a smallest number of times of an erase operation with data in a sector to be initialized.

34. The non-volatile semiconductor memory device of claim 1, further comprising:
a data address management table for storing information indicating an area in the memory cell array,
wherein the program sequence control circuit fixes data in the area indicated by the information stored in the data address management table.

35. The non-volatile semiconductor memory device of claim 25, wherein the long-term guaranteeing write operation section performs the additional write operation in the background when waiting for an input of the command.
